(19) United States
(12) Patent Application Publication
(10) Pub. No.: US 2025/0111495 A1
(43) Pub. Date: Apr. 3, 2025

(54) SUBSTRATE PROCESSING APPARATUS AND MONITORING METHOD

(71) Applicant: SCREEN Holdings Co., Ltd., Kyoto (JP)

(72) Inventors: Shinji SHIMIZU, Kyoto-shi, Kyoto (JP); Ryo YAMADA, Kyoto-shi, Kyoto (JP); Tatsuya MASUI, Kyoto-shi, Kyoto (JP); Yuichi DEBA, Kyoto-shi, Kyoto (JP); Miwa MIYAWAKI, Kyoto-shi, Kyoto (JP)

(21) Appl. No.: 18/832,880

(22) PCT Filed: Jan. 31, 2023
(86) PCT No.: PCT/JP2023/003049

§ 371 Date: Jul. 24, 2024

(30) Foreign Application Priority Data
Mar. 18, 2022 (JP) 2022-043753

(51) Int. Cl. G06T 7/00; G02B 27/00; G06T 7/60; H04N 23/52

(52) U.S. Cl. CPC G06T 7/0008; G06T 7/60; H04N 23/52; G02B 27/0006; G06T 2207/30148

(57) ABSTRACT

A substrate processing apparatus includes a chamber, a substrate holder, a nozzle, a camera, and a controller. The substrate holder holds a substrate in the chamber. The nozzle discharges a processing liquid toward the substrate held by the substrate holder. The camera captures an image of an imaging region including the monitoring target in the chamber, and generates captured image data. When the captured image data includes a droplet, the controller monitors the monitoring target using a region obtained by removing at least a part of a droplet region indicating the droplet in the captured image data.

### TECHNICAL FIELD

The present disclosure relates to a substrate processing apparatus and a monitoring method.

### BACKGROUND ART

Conventionally, in a process of manufacturing a semiconductor device or the like, various processing liquids such as pure water, a photoresist liquid, and an etching liquid are supplied to a substrate to perform various pieces of substrate processing such as cleaning processing and resist coating processing. A substrate processing apparatus in which discharges the processing liquid from a nozzle to a surface of the substrate while a substrate holder rotates the substrate in a horizontal posture is widely used as an apparatus performing substrate processing using these processing liquids.

Whether the position of the nozzle is appropriate is monitored in such the substrate processing apparatus. For example, in Patent Document 1, image capturing means such as a camera is provided to monitor the position of the nozzle.

### PRIOR ART DOCUMENT

### Patent Document

Patent Document 1: Japanese Patent Application Laid-Open No. 2015-173148

### SUMMARY

### Problem to be Solved by the Invention

In order to appropriately perform processing on the substrate, it is desirable to monitor not only the nozzle but also more monitoring targets.

For example, a guard receiving the processing solution scattered from a peripheral edge of the substrate is provided in the substrate processing apparatus. The guard has a tubular shape and surrounds the peripheral edge of the substrate. The guard is provided so as to ascend and descend, and the guard descends when the substrate is carried in and out. Consequently, collision between a conveyance robot carrying the substrate into and out of the substrate processing apparatus and the guard can be avoided. The guard ascends when the processing liquid is supplied to the surface of the substrate. An upper-end peripheral edge portion of the guard is positioned above the substrate due to the ascent of the guard. For this reason, the processing liquid scattered from the peripheral edge of the substrate is received by an inner peripheral surface of the guard.

When an abnormality is generated and the guard cannot move to an appropriate position, the collision between the guard and the conveyance robot cannot be appropriately avoided, or the processing liquid cannot be appropriately received by the guard.

Accordingly, it is conceivable that the camera captures an image of an imaging region including the guard to generate captured image data and an image processing part monitors the position of the guard based on the captured image data. However, when the droplets of the processing liquid adhere to an outer peripheral surface of the guard or the like, there is a fear that monitoring accuracy using the captured image data may be deteriorated.

In addition, even when the droplet adheres to the nozzle, there is a possibility that the monitoring accuracy of the position of the nozzle using the captured image data is lowered.

An object of the present disclosure is to provide a technique capable of monitoring the monitoring target with higher accuracy by reducing the influence of the droplet.

### Means to Solve the Problem

A first aspect is a substrate processing apparatus including: a chamber; a substrate holder that holds a substrate in the chamber; a nozzle that discharges a processing liquid toward the substrate held by the substrate holder; a camera that captures an image of an imaging region including a monitoring target in the chamber and generates captured image data; and a controller that monitors the monitoring target using a region obtained by removing at least a part of a droplet region indicating a droplet in the captured image data when the captured image data includes the droplet.

A second aspect is the substrate processing apparatus according to the first aspect, further including a storage that stores region data indicating a first region and a second region corresponding to surfaces of different objects in the captured image data, in which the controller monitors the monitoring target using a region excluding a contour region of the droplet region in the captured image data when the droplet is included in the first region, and the controller monitors the monitoring target using a region excluding an entire of the droplet region in the captured image data when the droplet is included in the second region.

A third aspect is the substrate processing apparatus according to the first aspect, in which the controller monitors the monitoring target using a region excluding a contour region of the droplet region in the captured image data for the droplet attached to a hydrophilic surface and excluding the entire of the droplet region in the captured image data for the droplet attached to a hydrophobic surface having lower wettability than the hydrophilic surface.

A fourth aspect is the substrate processing apparatus according to the third aspect, further including a storage that stores region data indicating a first region and a second region respectively corresponding to the hydrophilic surface and the hydrophobic surface in the captured image data, in which the controller determines whether a surface to which the droplet adheres is the hydrophilic surface or the hydrophobic surface based on the region data.

A fifth aspect is the substrate processing apparatus according to the fourth aspect, in which the controller updates the region data based on an operation time of the substrate processing apparatus, a number of processed substrates, or a time-related value indicating an elapsed time.

A six aspect is the substrate processing apparatus according to the third aspect, in which the controller determines whether a surface to which the droplet adheres is the hydrophilic surface or the hydrophobic surface based on the captured image data.

A seventh aspect is the substrate processing apparatus according to the six aspect, in which the controller calculates a size of the droplet region based on the captured image data, determines that the surface is the hydrophilic surface when the size of the droplet region is equal to or greater than a threshold, and determines that the surface is the hydrophobic surface when the size of the droplet is less than the threshold.

An eighth aspect is the substrate processing apparatus according to the sixth or seventh aspect, in which the controller determines whether the surface is the hydrophilic surface or the hydrophobic surface using a learned model.

A ninth aspect is the substrate processing apparatus according to any one of the first to eighth aspects, further including a hydrophilic and transparent camera guard provided between the camera and the imaging region, in which the controller determines whether the droplet adheres to the camera guard based on the captured image data, and monitors the monitoring target using a region obtained by excluding a contour region of the droplet region indicating the droplet adhering to the camera guard from the captured image data when the droplet adheres to the camera guard.

A tenth aspect is the substrate processing apparatus according to any one of the first to eighth aspects, further including a hydrophilic and transparent camera guard provided between the camera and the imaging region, in which the controller determines whether the droplet adheres to the camera guard based on the captured image data, and monitors the monitoring target using a region obtained by excluding the entire of the droplet region indicating the droplet adhering to the camera guard from the captured image data when the droplet adheres to the camera guard.

An eleventh aspect is the substrate processing apparatus according to any one of the first to eighth aspects, further including: a transparent camera guard provided between the camera and the imaging region; and a droplet remover that performs a removing operation removing at least a part of the droplet attached to the camera guard, in which when the captured image data includes the droplet, the droplet remover performs the removing operation and the controller monitors the monitoring target based on the captured image data captured by the camera after the removing operation.

A twelfth aspect is a monitoring method including: an imaging step of generating captured image data by a camera capturing an image of an imaging region including a monitoring target in a chamber, the chamber accommodating a substrate holder that holds a substrate and a nozzle that discharges a processing liquid toward the substrate held by the substrate holder; a droplet determination step of determining whether a droplet is included in the captured image data; and a monitoring step of monitoring the monitoring target using a region obtained by removing at least a part of a droplet region indicating the droplet in the captured image data when the droplet is included in the captured image data.

### Effects of the Invention

According to the first, second, and twelfth aspects, at least a part of the droplet region is not used, so that the monitoring target can be monitored with higher accuracy.

According to the third aspect, the droplets on the hydrophobic surface having low wettability are positioned in a raised state, so that the droplets function as a lens. Thus, a visual distortion is generated in the image of the hydrophobic surface through the droplet. In the third aspect, all of the droplet regions are deleted, so that a decrease in monitoring accuracy due to the distortion can be avoided.

On the other hand, the droplets on the hydrophilic surface having high wettability are positioned in a thinly spread state. Because the liquid surface is flat in the inner portion inside the contour portion of the droplet in planar view, the inner portion hardly functions as a lens, and the visual distortion is hardly generated in the image of the hydrophilic surface through the inner portion of the droplet. In the third aspect, the inner region is used except for the contour region of the droplet region, so that the monitoring can be performed based on more pixel values.

According to the fourth aspect, the wettability of the surface can be determined by a simple processing.

According to the fifth aspect, the deletion range of the droplet region can be appropriately determined according to a temporal change.

According to the sixth aspect, because the wettability of the surface is determined based on the captured image data, a user does not need to previously set data regarding the wettability.

According to the seventh aspect, the wettability can be determined with a relatively light processing load.

According to the eighth aspect, the wettability can be determined with high accuracy.

According to the ninth aspect, when the droplet adheres to the hydrophilic camera guard, the droplet is positioned in a thinly spread state. Using the inner region of the droplet region, a larger number of pixels can be used, so that the monitoring target can be monitored with higher accuracy.

According to the tenth aspect, when the droplet adheres to the hydrophobic camera guard, the droplet is positioned in a thickly raised state. Influence of the visual distortion due to the droplet region can be avoided using the region excluding the entire droplet region in the captured image data, so that the monitoring target can be monitored with higher accuracy.

According to the eleventh aspect, when the droplet adheres to the camera guard, the droplet is removed, so that the monitoring target can be monitored with less influence of the droplet.

### BRIEF DESCRIPTION OF DRAWINGS

FIG. 1 is a plan view schematically illustrating an example of a configuration of a substrate processing apparatus.

FIG. 2 is a plan view schematically illustrating an example of a configuration of a processing unit according to the first embodiment.

FIG. 3 is a longitudinal sectional view schematically illustrating the example of the configuration of the processing unit according to the first embodiment.

FIG. 4 is a functional block diagram schematically illustrating an example of an internal configuration of a controller.

FIG. 5 is a flowchart illustrating an example of a flow of substrate processing.

FIG. 6 is a view schematically illustrating an example of a captured image generated by capturing an image of an imaging region by a camera.

FIG. 7 is a flowchart illustrating an example of monitoring processing by the processing unit.

FIG. 8 is a flowchart illustrating a specific example of a monitoring step.

FIG. 9 is a view schematically illustrating an example of a state in which a droplet deletion step is performed on the captured image and a reference image.

FIG. 10 is a sectional view schematically illustrating an example of a droplet on an upper surface of a spin base and an outer peripheral surface of an outer guard.

FIG. 11 is a flowchart illustrating a specific example of a droplet deletion step according to a second embodiment.

FIG. 12 is a view schematically illustrating an example of a state in which the droplet deletion step is performed on the captured image and the reference image.

FIG. 13 is a flowchart illustrating an example of update of region data.

FIG. 14 is a flowchart illustrating an example of a method for determining a deletion range based on a size.

FIG. 15 is a flowchart illustrating an example of the method for determining the deletion range using a learned model.

FIG. 16 is a longitudinal sectional view schematically illustrating the example of a configuration of a processing unit according to a third embodiment.

FIG. 17 is a view schematically illustrating an example of the captured image when the camera captures an image at a first camera position.

FIG. 18 is a view schematically illustrating an example of the captured image when the camera captures the image at a second camera position.

FIG. 19 is a flowchart illustrating a specific example of a droplet deletion step according to the third embodiment.

FIG. 20 is a longitudinal sectional view schematically illustrating an example of a configuration of a processing unit according to a fourth embodiment.

FIG. 21 is a flowchart illustrating an example of an operation of the processing unit according to the fourth embodiment.

### DESCRIPTION OF EMBODIMENTS

Hereinafter, embodiments will be described with reference to the accompanying drawings. The drawings are schematically illustrated, and omission or simplification of a configuration is appropriately made for convenience. A mutual relationship between a size and a position of the configuration illustrated in the drawings is not necessarily described accurately, but can appropriately be changed.

In the following description, the same components are denoted by the same reference numeral, and it is assumed that names and functions of the same components are also similar. Accordingly, the detailed description of the same component is occasionally omitted in order to avoid duplication.

In the following description, even when ordinal numbers such as “first” or “second” are used, these terms are used only for convenience to facilitate understanding of contents of the embodiments, and are not limited to the order that can be generated by these ordinal numbers.

In the case where expressions indicating a relative or absolute positional relationship (for example, “in one direction”, “along one direction”, “parallel”, “orthogonal”, “center”, “concentric”, and “coaxial”) are used, the expressions shall not only strictly represent a positional relationship, but also represent a state of being displaced relative to an angle or a distance to an extent that a tolerance or a comparable function is obtained, unless otherwise specified. When expressions indicating an equal state (for example, “same”, “equal”, and “homogeneous”) are used, unless otherwise specified, the expressions shall not only represent a quantitatively strictly equal state, but also represent a state in which there is a difference in obtaining a tolerance or a similar function. In the case where expressions indicating a shape (for example, “quadrangular” or “cylindrical”) are used, unless otherwise specified, the expressions shall not only represent the shape geometrically and strictly, but also represent a shape having, for example, unevenness or chamfering within a range in which the same level of effect can be obtained. When expressions “comprising”, “owning”, “possessing”, “including” or “having” one component are used, the expressions are not an exclusive expression excluding presence of other components. When the expression “at least any one of A, B, and C” is used, the expression includes only A, only B, only C, any two of A, B and C, and all of A, B and C.

### First Embodiment

### <Overall Configuration of Substrate Processing Apparatus>

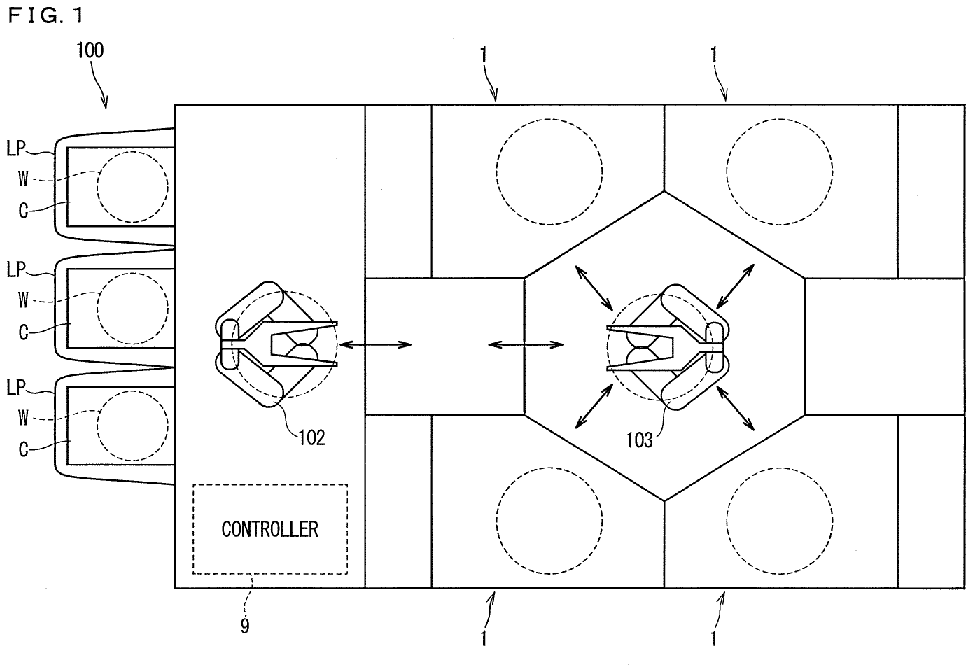

FIG. 1 is a plan view schematically illustrating an example of a configuration of a substrate processing apparatus 100. The substrate processing apparatus 100 is a single wafer type processing apparatus that processes a substrates W to be processed one by one. The substrate processing apparatus 100 performs liquid processing on the substrate W using a chemical liquid and a rinse liquid such as pure water, and then performs drying processing. For example, the substrate W is a semiconductor substrate and has a disk shape. For example, a mixed solution (SC1) of ammonia and a hydrogen peroxide solution, a mixed aqueous solution (SC2) of hydrochloric acid and a hydrogen peroxide solution, or a DHF solution (dilute hydrofluoric acid) is used as the chemical liquid. In the following description, the chemical liquid, the rinse liquid, an organic solvent, and the like are collectively referred to as a “processing liquid”. Not only cleaning processing but also a chemical liquid removing an unnecessary film, the chemical liquid for etching, or the like are included in the “processing liquid”.

The substrate processing apparatus 100 includes a plurality of processing units 1, a load port LP, an indexer robot 102, a main conveyance robot 103, and a controller 9.

The load port LP is an interface part that carries in and out the substrate W between the substrate processing apparatus 100 and the outside. A container (also referred to as a carrier) that accommodates a plurality of unprocessed substrates W is carried into the load port LP from the outside. The load port LP can hold a plurality of carriers. As described later, each substrate W is taken out from the carrier by the substrate processing apparatus 100, processed, and accommodated in the carrier again. The carrier that accommodates the plurality of processed substrates W is carried out from the load port LP to the outside.

The indexer robot 102 conveys the substrate W between each carrier held in the load port LP and the main conveyance robot 103. The main conveyance robot 103 conveys the substrate W between each processing unit 1 and the indexer robot 102.

The processing unit 1 performs the liquid processing and the drying processing on one substrate W. In the substrate processing apparatus 100 of the present embodiment, twelve processing units 1 having the same configuration are disposed. Specifically, four towers each including three processing units 1 stacked in a vertical direction are disposed so as to surround a periphery of the main conveyance robot 103. In FIG. 1, one of the processing units 1 that are stacked in three stages is schematically illustrated. The number of processing units 1 in the substrate processing apparatus 100 is not limited to twelve, but may be appropriately changed.

The main conveyance robot 103 is installed at a center of the four towers in which the processing units 1 are stacked. The main conveyance robot 103 carries the substrate W to be processed received from the indexer robot 102 into each processing unit 1. In addition, the main conveyance robot 103 carries out the processed substrate W from each processing unit 1 and transfers the substrate W to the indexer robot 102. The controller 9 controls operation of each component of the substrate processing apparatus 100.

One of the 12 processing units 1 loaded on the substrate processing apparatus 100 will be described below.

### <Processing Unit>

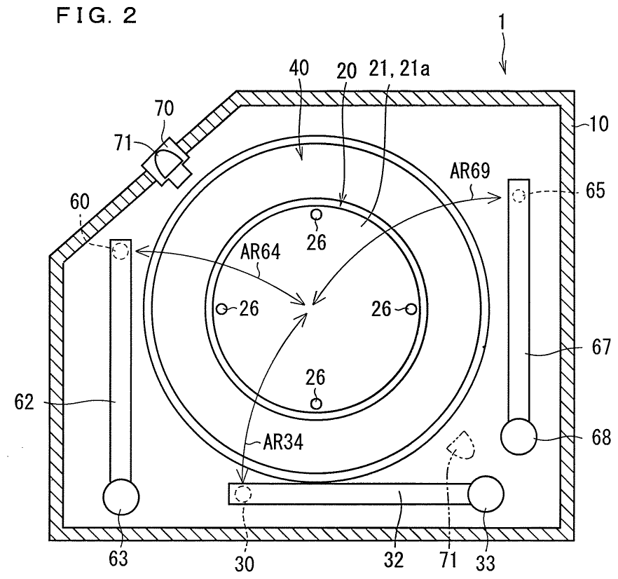

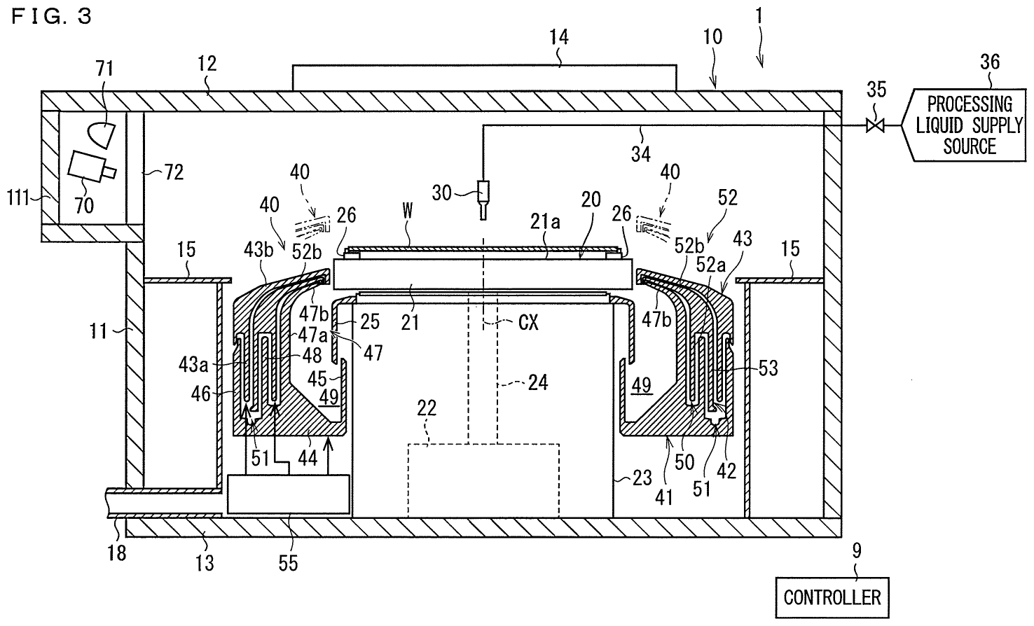

FIG. 2 is a plan view schematically illustrating an example of a configuration of the processing unit 1 according to the first embodiment. FIG. 3 is a longitudinal sectional view schematically illustrating the example of the configuration of the processing unit 1 according to the first embodiment.

In the examples of FIGS. 2 and 3, the processing unit 1 includes a substrate holder 20, a first nozzle 30, a second nozzle 60, a third nozzle 65, a guard part 40, and a camera 70.

In the examples of FIGS. 2 and 3, the processing unit 1 also includes a chamber 10. The chamber 10 includes a side wall 11 along the vertical direction, a ceiling wall 12 that closes an upper side of a space surrounded by the side wall 11, and a floor wall 13 that closes a lower side. A processing space is formed in a space surrounded by the side wall 11, the ceiling wall 12, and the floor wall 13. On a part of the side wall 11 of the chamber 10, a carry-in and -out port for the main conveyance robot 103 to carry-in and -out the substrate W and a shutter that opens and closes the carry-in and -out port are provided (both are not illustrated). The chamber 10 accommodates the substrate holder 20, the first nozzle 30, the second nozzle 60, the third nozzle 65, and the guard part 40.

In the example of FIG. 3, a fan filter unit (FFU) 14, which further cleans the air in the clean room where the substrate processing apparatus 100 is installed and supplies the air to the processing space in the chamber 10, is attached to the ceiling wall 12 of the chamber 10. The fan filter unit 14 includes a fan and a filter (for example, a high efficiency particulate air (HEPA) filter) that take in the air in the clean room to send the air into the chamber 10, and forms a down flow of clean air in the processing space in the chamber 10. In order to uniformly disperse the clean air supplied from the fan filter unit 14, a punching plate having a large number of blow-out holes may be provided immediately below the ceiling wall 12.

The substrate holder 20 holds the substrate W in a horizontal posture (posture in which the normal line is along the vertical direction) and rotates the substrate W around a rotation axis CX (see FIG. 3). The rotation axis CX is an axis along the vertical direction and passing through the center portion of the substrate W. The substrate holder 20 is also referred to as a spin chuck. FIG. 2 illustrates the substrate holder 20 while the substrate W is not held.

In the examples of FIGS. 2 and 3, the substrate holder 20 includes a disk-shaped spin base 21 provided in a horizontal posture. An outer diameter of the disk-shaped spin base 21 is slightly larger than a diameter of the circular substrate W held by the substrate holder 20 (see FIG. 3). Accordingly, the spin base 21 includes an upper surface 21a opposite to the entire lower surface of the substrate W to be held in the vertical direction. In this case, as an example, wettability of the upper surface 21a of the spin base 21 is high. In other words, the upper surface 21a is a hydrophilic surface. For example, a contact angle of the hydrophilic surface here is less than about 45 degrees.

In the examples of FIGS. 2 and 3, a plurality of (four in the present embodiment) chuck pins 26 are erected on a peripheral edge portion of the upper surface 21a of the spin base 21. The plurality of chuck pins 26 is arranged at equal intervals along a circumference corresponding to the peripheral edge of the circular substrate W. Each of the chuck pins 26 is provided so as to be drivable between a holding position in contact with the peripheral edge of the substrate W and an open position away from the peripheral edge of the substrate W. The plurality of chuck pins 26 are driven in conjunction with each other by a link mechanism (not illustrated) accommodated in the spin base 21. The substrate holder 20 can hold the substrate W in a horizontal posture close to the upper surface 21a above the spin base 21 by stopping the plurality of chuck pins 26 at the respective holding positions (see FIG. 3), and can release the holding of the substrate W by stopping the plurality of chuck pins 26 at the respective opening positions.

In the example of FIG. 3, an upper end of a rotation shaft 24 extending along the rotation axis CX is connected to the lower surface of the spin base 21. A spin motor 22 that rotates the rotation shaft 24 is provided below the spin base 21. The spin motor 22 rotates the spin base 21 in a horizontal plane by rotating the rotation shaft 24 around the rotation axis CX. Consequently, the substrate W held by the chuck pin 26 also rotates around the rotation axis CX.

In the example of FIG. 3, a tubular cover member 23 is provided so as to surround the spin motor 22 and the rotation shaft 24. The lower end of the cover member 23 is fixed to the floor wall 13 of the chamber 10, and the upper end reaches immediately below the spin base 21. In the example of FIG. 3, a flange-shaped member 25, which protrudes substantially horizontally outward from the cover member 23 and further bends and extends downward, is provided in the upper end portion of the cover member 23.

The first nozzle 30 discharges the processing liquid toward the substrate W and supplies the processing liquid to the substrate W. In the example of FIG. 2, the first nozzle 30 is attached to a tip of a nozzle arm 32. The nozzle arm 32 extends horizontally, and a base end thereof is connected to a nozzle support column 33. The nozzle support column 33 extends along the vertical direction and is provided so as to be rotatable around an axis along the vertical direction by an arm driving motor (not illustrated). When the nozzle support column 33 rotates, the first nozzle 30 moves in an arc shape between a nozzle processing position and a nozzle standby position in a space vertically above the substrate holder 20 as indicated by an arrow AR34 in FIG. 2. The nozzle processing position is a position at which the first nozzle 30 discharges the processing liquid onto the substrate W, and for example, is a position opposite to a central portion of the substrate W in the vertical direction. The nozzle standby position is a position at which the first nozzle 30 does not discharge the processing liquid onto the substrate W, and for example, is a position radially outside the peripheral edge of the substrate W. At this point, the radial direction is the radial direction with respect to the rotation axis CX. FIG. 2 illustrates the first nozzle 30 located at the nozzle standby position, and FIG. 3 illustrates the first nozzle 30 located at the nozzle processing position.

As illustrated in FIG. 3, the first nozzle 30 is connected to a processing liquid supply source 36 through a supply pipe 34. The processing liquid supply source 36 includes a tank that stores the processing liquid. A valve 35 is provided in the supply pipe 34. When the valve 35 is opened, the processing liquid is supplied from the processing liquid supply source 36 to the first nozzle 30 through the supply pipe 34, and discharged from a discharge port formed on the lower end surface of the first nozzle 30. The first nozzle 30 may be configured to be supplied with a plurality of kinds of processing liquids (including at least pure water).

The second nozzle 60 is attached to a tip of a nozzle arm 62, and a base end of the nozzle arm 62 is connected to a nozzle support column 63. When the arm driving motor (not illustrated) rotates the nozzle support column 63, the second nozzle 60 moves in an arc shape in a space vertically above the substrate holder 20 as indicated by an arrow AR64. Similarly, a third nozzle 65 is attached to a tip of a nozzle arm 67, and the proximal end of the nozzle arm 67 is connected to a nozzle support column 68. When the arm driving motor (not illustrated) rotates the nozzle support column 68, the third nozzle 65 moves in an arc shape in the space vertically above the substrate holder 20 as indicated by an arrow AR69.

Similarly to the first nozzle 30, each of the second nozzle 60 and the third nozzle 65 is connected to a processing liquid supply source (not illustrated) through a supply pipe (not illustrated). A valve is provided in each supply pipe, and supply and stop of the processing liquid is switched by opening and closing the valve. The number of nozzles provided in the processing unit 1 is not limited to three, but may be at least one.

In the liquid processing, for example, the processing unit 1 causes the first nozzle 30 to discharge the processing liquid toward the upper surface of the substrate W while rotating the substrate W by the substrate holder 20. The processing liquid attached to the upper surface of the substrate W spreads on the upper surface of the substrate W by receiving centrifugal force accompanying the rotation, and scatters from the peripheral edge of the substrate W. By this liquid processing, processing according to the kind of the processing liquid can be performed on the upper surface of the substrate W.

The guard part 40 is a member that receives the processing liquid scattered from the peripheral edge of the substrate W. The guard part 40 has a tubular shape surrounding the substrate holder 20, and for example, includes a plurality of guards that can ascend and descend independently of each other. The guard may also be referred to as a processing cup. In the example of FIG. 3, an inner guard 41, a middle guard 42, and an outer guard 43 are illustrated as the plurality of guards. Each of the guards 41 to 43 surrounds the periphery of the substrate holder 20 and has a shape substantially rotationally symmetric with respect to the rotation axis CX.

In the example of FIG. 3, the inner guard 41 integrally includes a bottom part 44, an inner wall part 45, an outer wall part 46, a first guide part 47, and a middle wall part 48. The bottom part 44 has an annular shape in planar view. The inner wall part 45 and the outer wall part 46 have a cylindrical shape, and are erected on an inner peripheral edge and an outer peripheral edge of the bottom part 44, respectively. The first guide part 47 includes a tubular part 47a erected on the bottom part 44 between the inner wall part 45 and the outer wall part 46 and an inclined part 47b that approaches the rotation axis CX as it goes vertically upward from the upper end of the tubular part 47a. The middle wall part 48 has a cylindrical shape, and is erected on the bottom part 44 between the first guide part 47 and the outer wall part 46.

In the state where the guards 41 to 43 are raised (see an imaginary line in FIG. 3), the processing liquid scattered from the peripheral edge of the substrate W is received by the inner peripheral surface of the first guide part 47, flows down along the inner peripheral surface, and is received by a disposal groove 49. The disposal groove 49 is an annular groove formed by the inner wall part 45, the first guide part 47, and the bottom part 44. An exhaust liquid mechanism (not illustrated), which discharges the processing liquid and forcibly exhausts the inside of the disposal groove 49, is connected to the disposal groove 49.

The middle guard 42 integrally includes a second guide part 52 and a cylindrical processing liquid separation wall 53 connected to the second guide part 52. The second guide part 52 includes a tubular part 52a having a cylindrical shape and an inclined part 52b that approaches the rotation axis CX as it goes vertically upward from the upper end of the tubular part 52a. The inclined part 52b is located vertically above the inclined part 47b of the inner guard 41, and provided so as to overlap the inclined part 47b in the vertical direction. The tubular part 52a is accommodated in an annular inside recovery groove 50. The inside recovery groove 50 is a groove formed by the first guide part 47, the middle wall part 48, and the bottom part 44.

In the state where only the guards 42, 43 are raised, the processing liquid from the peripheral edge of the substrate W is received by the inner peripheral surface of the second guide part 52, flows down along the inner peripheral surface, and is received by the inside recovery groove 50.

The processing liquid separation wall 53 has a cylindrical shape, and an upper end thereof is connected to the second guide part 52. The processing liquid separation wall 53 is accommodated in the annular outside recovery groove 51. The outside recovery groove 51 is a groove formed by the middle wall part 48, the outer wall part 46, and the bottom part 44.

The outer guard 43 is located outside the middle guard 42, and has a function as a third guide part that guides the processing liquid to the outside recovery groove 51. The outer guard 43 integrally includes a cylindrical tubular part 43a and an inclined part 43b approaching the rotation axis CX as it goes vertically upward from the upper end of the tubular part 43a. The tubular part 43a is accommodated in the outside recovery groove 51, and the inclined part 43b is located vertically above the inclined part 52b and provided so as to vertically overlap the inclined part 52b.

In the state where only the outer guard 43 is raised, the processing liquid from the peripheral edge of the substrate W is received by the inner peripheral surface of the outer guard 43, flows down along the inner peripheral surface, and is received by the outside recovery groove 51.

The inside recovery groove 50 and the outside recovery groove 51 are connected to a recovery mechanism (not illustrated) that recovers the processing liquid in a recovery tank provided outside the processing unit 1.

For example, the inner guard 41, the middle guard 42, and the outer guard 43 are formed of a resin such as a fluorine-based resin. In this case, as an example, the wettability of the surfaces of the inner guard 41, the middle guard 42, and the outer guard 43 is lower than the wettability of the upper surface 21a of the spin base 21. In other words, the surface of each of the guards 41 to 43 is a hydrophobic surface. For example, the hydrophobic surface as used herein refers to a surface having a contact angle larger than about 45 degrees. The value of the contact angle for distinguishing the hydrophobic surface and the hydrophilic surface is not necessarily limited to 45 degrees, but may be appropriately determined by the user.

The guards 41 to 43 can be ascended and descended by a guard ascending and descending mechanism 55. The guard ascending and descending mechanism 55 ascends and descends the guards 41 to 43 between a guard processing position and a guard standby position such that the guards 41 to 43 do not collide with each other. The guard processing position is a position where the upper-end peripheral edge portion of the target guard to be ascended and descended is located above the upper surface of the substrate W, and the guard standby position is a position where the upper-end peripheral edge portion of the target guard is located below the upper surface 21a of the spin base 21. At this point, the upper-end peripheral edge portion is an annular portion that forms an upper-end opening of the target guard. In the example of FIG. 3, the guards 41 to 43 are located at the guard standby position. For example, the guard ascending and descending mechanism 55 includes a ball screw mechanism and a motor or an air cylinder.

A partition plate 15 is provided so as to vertically partition an inside space of the chamber 10 around the guard part 40. A through-hole and a notch (not illustrated) penetrating in the thickness direction of the partition plate 15 may be formed, and in the present embodiment, a through-hole passing the nozzle support column 33, the nozzle support column 63, and the nozzle support column 68 is made. An outer peripheral end of the partition plate 15 is connected to the side wall 11 of the chamber 10. An inner peripheral edge of the partition plate 15 surrounding the guard part 40 is formed in a circular shape having a diameter larger than the outer diameter of the outer guard 43. Accordingly, the partition plate 15 does not obstruct the ascent and descent of the outer guard 43.

In the example of FIG. 3, an exhaust duct 18 is provided in a part of the side wall 11 of the chamber 10 and in the vicinity of the floor wall 13. The exhaust duct 18 is communicably connected to an exhaust mechanism (not illustrated). In the clean air flowing down in the chamber 10, the air passing between the guard part 40 and the partition plate 15 is discharged from the exhaust duct 18 to the outside of the apparatus.

The camera 70 is used to monitor the state of a monitoring target in the chamber 10. For example, the monitoring target includes at least one of the substrate holder 20, the first nozzle 30, the second nozzle 60, the third nozzle 65, and the guard part 40. The camera 70 captures an image of an imaging region including the monitoring target, generates captured image data (hereinafter, simply referred to as a captured image), and outputs the captured image to the controller 9. As will be described in detail later, the controller 9 monitors the state of the monitoring target based on the captured image.

The camera 70 includes a solid-state imaging element such as a charge coupled device (CCD) or a complementary metal oxide semiconductor (CMOS) and an optical system such as a lens. In the example of FIG. 3, the camera 70 is installed at an imaging position vertically above the substrate W held by the substrate holder 20. In the example of FIG. 3, the imaging position is set vertically above the partition plate 15 and radially outside with respect to the guard part 40. At this point, the radial direction is the radial direction with respect to the rotation axis CX.

In the example of FIG. 3, a concave part (hereinafter, referred to as a recessed wall part 111) accommodating the camera 70 is formed on the side wall 11 of the chamber 10. The recessed wall part 111 has a shape recessed outward with respect to other parts of the side wall 11. The camera 70 is accommodated inside the recessed wall part 111. In the example of FIG. 3, a transparent camera guard 72 is provided in front of the camera 70 in the imaging direction. The camera guard 72 is a transparent member having high translucency with respect to a wavelength of light detected by the camera 70. For this reason, the camera 70 can capture the image of the imaging region in the processing space through the camera guard 72. In other words, the camera guard 72 is provided between the camera 70 and the imaging region. For example, the transmittance of the camera guard 72 in a detection wavelength range of the camera 70 is equal to or greater than 60%, preferably equal to or greater than 80%. For example, the camera guard 72 is formed of a transparent material such as quartz glass. In the example of FIG. 3, the camera guard 72 has a plate shape, and forms an accommodation space of the camera 70 together with the recessed wall part 111 of the side wall 11. When the camera guard 72 is provided, the camera 70 can be protected from the processing liquid and a volatile component of the processing liquid in the processing space.

For example, the imaging region of the camera 70 includes parts of the substrate holder 20 and the guard part 40. In the example of FIG. 3, the camera 70 captures the image of the imaging region obliquely downward from the imaging position. In other words, the imaging direction of the camera 70 is inclined vertically downward from the horizontal direction.

In the example of FIG. 3, an illumination part 71 is provided at a position vertically above the partition plate 15. As a specific example, the illumination part 71 is also provided inside the recessed wall part 111. In the case where the inside of the chamber 10 is a dark room, the controller 9 may control the illumination part 71 such that the illumination part 71 irradiates the imaging region when the camera 70 captures the image. Illumination light from the illumination part 71 passes through the camera guard 72 and is emitted into the processing space.

A hardware configuration of the controller 9 is the same as that of a general computer. That is, the controller 9 includes a data processing part such as a CPU that performs various kinds of arithmetic processing, a non-temporary storage part such as a read only memory (ROM) that is a read-only memory storing a basic program, and a temporary storage part such as a random access memory (RAM) that is a readable and writable memory storing various kinds of information. When the CPU of the controller 9 executes a predetermined processing program, each operation mechanism of the substrate processing apparatus 100 is controlled by the controller 9, and the processing in the substrate processing apparatus 100 proceeds. The controller 9 may be implemented by a dedicated hardware circuit that does not need software implementing a function of the controller 9.

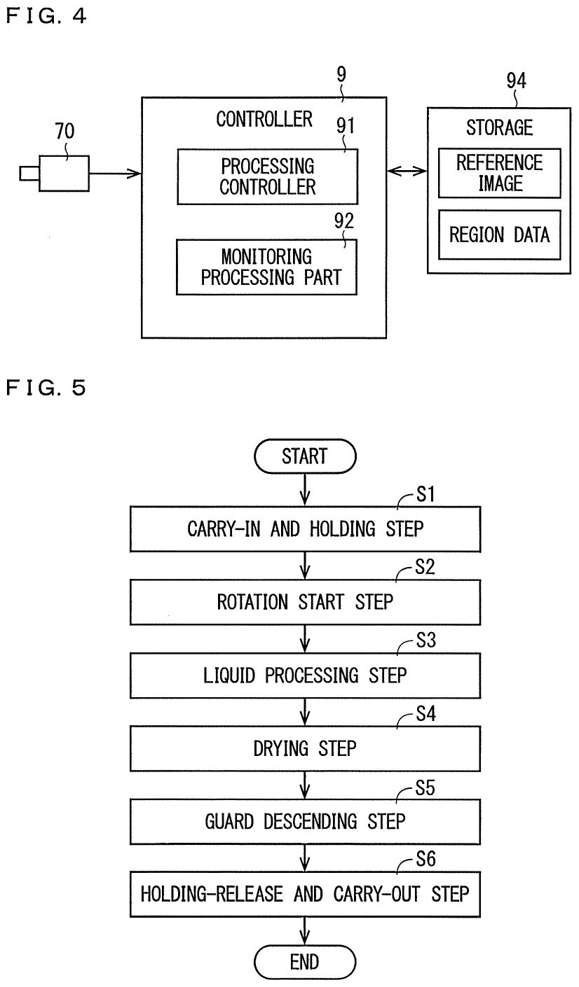

FIG. 4 is a functional block diagram schematically illustrating an example of an internal configuration of the controller 9. As illustrated in FIG. 4, the controller 9 includes a processing controller 91 and a monitoring processing part 92.

The processing controller 91 controls each component of the processing unit 1. More specifically, the processing controller 91 controls the spin motor 22, various valves such as and the valve 35, the arm driving motor that rotates each of the nozzle support columns 33, 63, 68, the guard ascending and descending mechanism 55, the fan filter unit 14, and the camera 70. The processing controller 91 controls these configurations according to a predetermined procedure, so that the processing unit 1 can perform the processing on the substrate W.

### Example of Flow of Substrate Processing

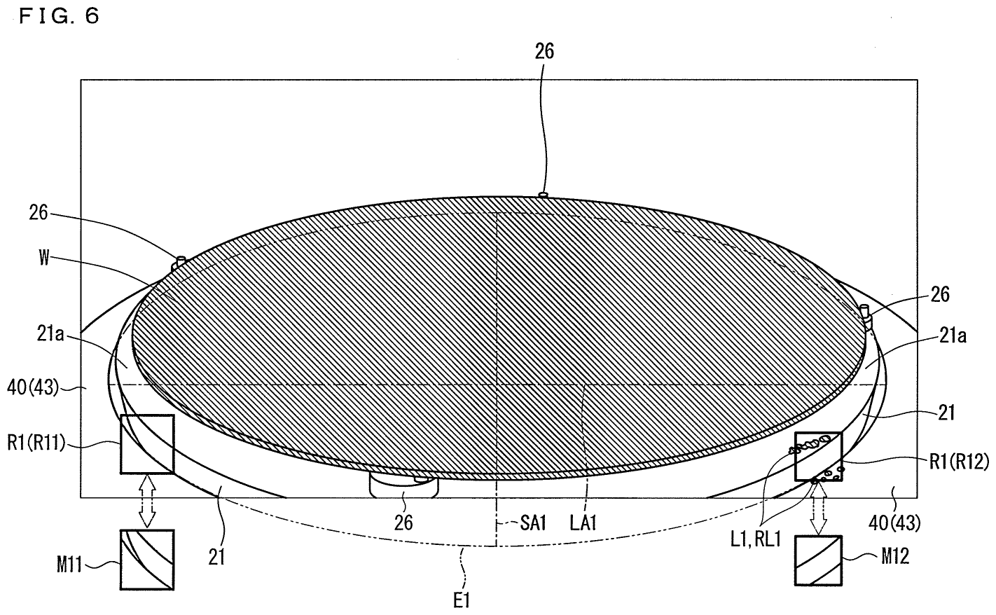

An example of a specific flow of processing for the substrate W will be briefly described below. FIG. 5 is a flowchart illustrating an example of a flow of substrate processing. Initially, the guards 41 to 43 stop at the guard standby position, and the nozzles 30, 60, 65 stop at the nozzle standby position. Although the controller 9 controls each configuration to execute a predetermined operation to be described later, each configuration itself will be adopted and described below as a subject of the operation.

First, the main conveyance robot 103 carries the unprocessed substrate W in the processing unit 1, and the substrate holder 20 holds the substrate W (step S1: carry-in and holding step). Because the guard part 40 is initially stopped at the guard standby position, collision between a hand of the main conveyance robot 103 and the guard part 40 can be avoided when the substrate W is carried in. When the substrate W is passed to the substrate holder 20, the plurality of chuck pins 26 move to the respective holding positions, whereby the plurality of chuck pins 26 holds the substrate W.

Subsequently, the spin motor 22 starts the rotation of the substrate W (step S2: rotation start step). Specifically, the spin motor 22 rotates the spin base 21 to rotate the substrate W held by the substrate holder 20.

Subsequently, the processing unit 1 performs various kinds of liquid processing on the substrate W (step S3: liquid processing step). For example, the processing unit 1 performs chemical liquid processing. First, the guard ascending and descending mechanism 55 ascends the guard corresponding to the chemical liquid in the guards 41 to 43 to the guard processing position. The guard for the chemical liquid is not particularly limited, but for example, may be the outer guard 43. In this case, the guard ascending and descending mechanism 55 stops the inner guard 41 and the middle guard 42 at the guard standby positions, and ascends the outer guard 43 to the guard processing position.

Subsequently, the processing unit 1 supplies the chemical liquid to the substrate W. At this point, it is assumed that the first nozzle 30 supplies the processing liquid. Specifically, the arm driving motor moves the first nozzle 30 to the nozzle processing position, and the valve 35 is open to discharge the chemical liquid from the first nozzle 30 toward the substrate W. Consequently, the chemical liquid spreads over the upper surface of the rotating substrate W and scatters from the peripheral edge of the substrate W. At this point, the chemical liquid acts on the upper surface of the substrate W, and the processing (for example, cleaning processing) corresponding to the chemical liquid is performed on the substrate W. The chemical liquid scattered from the peripheral edge of the substrate W is received by the inner peripheral surface of the guard part 40 (for example, the outer guard 43). When the chemical liquid processing is sufficiently performed, the processing unit 1 stops the supply of the chemical liquid.

Subsequently, the processing unit 1 performs rinse processing on the substrate W. The guard ascending and descending mechanism 55 adjusts an ascending and descending state of the guard part 40 as necessary. That is, when the guard for the rinse liquid is different from the guard for the chemical liquid, the guard ascending and descending mechanism 55 moves the guard corresponding to the rinse liquid in the guards 41 to 43 to the guard processing position. The guard for the rinse liquid is not particularly limited, but may be the inner guard 41. In this case, the guard ascending and descending mechanism 55 ascends the guards 41 to 43 to the respective guard processing positions.

Subsequently, the first nozzle 30 discharges the rinse liquid toward the upper surface of the substrate W. For example, the rinse liquid is the pure water. The rinse liquid spreads over the upper surface of the rotating substrate W, and scatters from the peripheral edge of the substrate W while pushing away the chemical liquid on the substrate W. The processing liquid (mainly the rinse liquid) scattered from the peripheral edge of the substrate W is received by the inner peripheral surface of the guard part 40 (for example, the inner guard 41). When the rinse processing is sufficiently performed, the processing unit 1 stops the supply of the rinse liquid.

The processing unit 1 may supply a volatile rinse liquid such as isopropyl alcohol having high volatility to the substrate W as necessary. When the guard for the volatile rinse liquid is different from the above-described guard for the rinse liquid, the guard ascending and descending mechanism 55 may move the guard corresponding to the volatile rinse liquid in the guards 41 to 43 to the guard processing position. When the rinsing processing is completed, the first nozzle 30 moves to the nozzle standby position.

Subsequently, the processing unit 1 performs drying processing on the substrate W (step S4: drying step). For example, the spin motor 22 increases the rotation speed of the substrate W to dry the substrate W (what is called spin dry). Also in the drying processing, the processing liquid scattered from the peripheral edge of the substrate W is received by the inner peripheral surface of the guard part 40. When the drying processing is sufficiently performed, the spin motor 22 stops the rotation of the substrate W.

Subsequently, the guard ascending and descending mechanism 55 descends the guard part 40 to the guard standby position (step S5: guard descending step). That is, the guard ascending and descending mechanism 55 descends each of the guards 41 to 43 to the guard standby position.

Subsequently, the substrate holder 20 releases the holding of the substrate W, and the main conveyance robot 103 takes out the processed substrate W from the processing unit 1 (step S6: holding-release and carry-out step). The guard part 40 is stopped at the guard standby position when the substrate W is carried out, so that the collision between the hand of the main conveyance robot 103 and the guard part 40 can be avoided.

As described above, the various components in the processing unit 1 are appropriately operated to process the substrate W. For example, the substrate holder 20 holds or releases the substrate W. The first nozzle 30 moves between the nozzle processing position and the nozzle standby position, and discharges the processing liquid toward the substrate W at the nozzle processing position. Each of the guards 41 to 43 of the guard part 40 moves to a height position corresponding to each step.

### <Monitoring Processing>

The substrate W is processed by appropriately operating the above components. Conversely, when at least one of the above components cannot be appropriately operated, the processing of the substrate W can be impaired. Accordingly, the processing unit 1 sets at least one of the above components as the monitoring target and monitors the state of the monitoring target.

As is apparent from the operation of the substrate processing described above, in the liquid processing step, the processing liquid is discharged toward the rotating substrate W. Consequently, the processing liquid scatters in the substrate W. Although this processing liquid is generally received by the guard part 40, there is a possibility that the processing liquid bounces off the guard part 40 and adhere to another component, or there is also a possibility that the processing liquid bounces off the upper surface of the substrate W and adhere to another component (for example, the outer peripheral surface of the outer guard 43). When the droplet adheres, the droplet is also included in the captured image, and there is a risk that this droplet lowers the monitoring accuracy of the monitoring target.

Hereinafter, the description will be given while the outer guard 43 is adopted as an example of the monitoring target. FIG. 6 is a view schematically illustrating an example of the captured image generated by capturing the image of the imaging region by the camera 70. The captured image of FIG. 6 includes the entire upper surface of the substrate W held by the substrate holder 20. In other words, the camera 70 is provided at a position where the entire substrate W is included in the imaging region. In the example of FIG. 6, the substrate holder 20 holds the substrate W, and the outer guard 43 is stopped at the guard standby position. Because the camera 70 captures the image of the imaging region obliquely downward, the substrate W having a circular shape in planar view has an elliptical shape in an imaging screen, and similarly, the upper-end peripheral edge of the outer guard 43 having the circular shape in planar view has a shape along the ellipse in the captured image. In the example of FIG. 6, a virtual ellipse E1 along which the upper-end peripheral edge of the outer guard 43 extends is also illustrated.

For example, such the captured image is obtained by the camera 70 capturing the image of the imaging region while the outer guard 43 descends to the guard standby position in the guard descending step (step S5). When the outer guard 43 can appropriately descend to the guard standby position in the guard descending step, the collision between the hand of the main conveyance robot 103 and the guard part 40 can be appropriately avoided in the next holding-release and carry-out step (step S6). On the other hand, when the outer guard 43 cannot descend to the guard standby position due to the abnormality, the hand of the main conveyance robot 103 and the guard part 40 may collide with each other in the holding-release and carry-out step. Thus, the monitoring processing part 92 monitors the position of the outer guard 43 based on the captured image.

Meanwhile, in the captured image of FIG. 6, a droplet L1 adheres to the upper surface 21a of the spin base 21 and the outer peripheral surface of the outer guard 43. For example, in the liquid processing step (step S3) before the guard descending step, the processing liquid adheres to the upper surface 21a of the spin base 21 and the outer peripheral surface of the outer guard 43, whereby the droplets L1 remain on the upper surface 21a of the spin base 21 and the outer peripheral surface of the outer guard 43 also in the guard descending step. In this case, because the upper surface 21a of the spin base 21 is a surface having high wettability, the droplet L1 is positioned in a relatively thin spread state on the upper surface 21a of the spin base 21. Furthermore, in this case, because the outer peripheral surface of the outer guard 43 is a surface having lower wettability than that of the upper surface 21a, the droplet L1 is positioned in a relatively thick raised state on the outer peripheral surface of the outer guard 43.

When the droplet L1 exists in the outer guard 43 itself or around the outer guard 43 that is the monitoring target, the monitoring accuracy based on the captured image including the droplet L1 may be reduced.

Thus, as will be described in detail later, when the captured image includes the droplet L1, the monitoring processing part 92 generates removed image data by deleting at least a part of a droplet region RL1 indicating the droplet L1 from the captured image, and monitors the state of the monitoring target based on the removed image data. That is, as will be described in detail later, the monitoring processing part 92 monitors the state of the monitoring target using a region obtained by removing at least a part of the droplet region RL1 from the captured image.

In describing this monitoring processing, first, an example of a monitoring algorithm of the outer guard 43 in the state where the droplet L1 does not exist will be outlined. In the example of FIG. 6, a guard determination region R1 is set in the captured image. The guard determination region R1 is a region used for monitoring the outer guard 43 and includes at least a part of the outer guard 43. In the example of FIG. 6, the guard determination region R1 is set to a region including a part of the upper-end peripheral edge of the outer guard 43 normally located at the guard standby position. In the example of FIG. 6, a plurality of (two in FIG. 6) guard determination regions R11, R12 are set as the guard determination region R1. Each of the guard determination regions R11, R12 is set to include a part of the upper peripheral edge of the outer guard 43 below a major axis LA1 of the ellipse E1 in the imaging region. In addition, the guard determination regions R11, R12 are set on opposite sides to each other with respect to a minor axis SAI of the ellipse E1.

The upper region in each of the guard determination regions R11, R12 includes a part of the upper surface 21a of the spin base 21, and the lower region in each of the guard determination regions R11, R12 includes a part of the outer peripheral surface of the outer guard 43. In the example of FIG. 6, the guard determination region R11 does not include the droplet L1, and the guard determination region R12 includes the droplet L1.

At this point, a reference image M1 for guard position determination is previously stored in the storage 94. In the reference image M1, the droplet L1 is not attached and the outer guard 43 is normally located at the guard standby position. For example, such the reference image M1 is generated based on the captured image captured by the camera 70 when the droplet L1 is not attached and the outer guard 43 is normally located at the guard standby position. In FIG. 6, reference images M11, M12 respectively corresponding to the guard determination regions R11, R12 are illustrated as the reference image M1. The reference image M11 is an image in the same region as the guard determination region R11, and the reference image M12 is an image in the same region as the guard determination region R12.

At this point, focusing on the guard determination region R11 not including the droplet L1, an example of the monitoring algorithm of the outer guard 43 when the droplet L1 does not exist will be outlined. When the outer guard 43 is normally located at the guard standby position, a similarity ratio between the guard determination region R11 and the reference image M11 increases (see FIG. 6). On the other hand, when the outer guard 43 is located at a position higher than the guard standby position in the captured image, the similarity ratio between the guard determination region R11 and the reference image M11 decreases. Conversely, when the similarity ratio is high, it can be determined that the outer guard 43 is normally located at the guard standby position, and when the similarity ratio is low, it can be determined that the abnormality is generated in the outer guard 43.

Accordingly, when the captured image does not include the droplet L1, the monitoring processing part 92 calculates the similarity ratio between the guard determination region R11 and the reference image M11 and the similarity ratio between the guard determination region R12 and the reference image M12 as described later. The monitoring processing part 92 determines that the outer guard 43 is normally located in the guard standby position when both the similarity ratios are equal to or greater than a predetermined guard threshold, and the monitoring processing part 92 determines that the abnormality related to the outer guard 43 is generated when at least one of the similarity ratios is less than the guard threshold.

On the other hand, when the droplet L1 is included in the captured image, sometimes the similarity ratio decreases even when the outer guard 43 normally stops at the guard standby position. For example, the guard determination region R12 in FIG. 6 includes the droplet L1. In this case, even when the outer guard 43 is normally located at the guard standby position, the similarity ratio between the guard determination region R12 and the reference image M12 decreases. This is because the guard determination region R12 includes the droplet L1, whereas the reference image M12 does not include the droplet L1. That is, this difference causes the decrease in similarity ratio.

Thus, in the first embodiment, when the droplet L1 is included in the captured image, the monitoring processing part 92 monitors the state of the monitoring target using a region obtained by excluding at least a part of the droplet region RL1 indicating the droplet L1 in the captured image as described later.

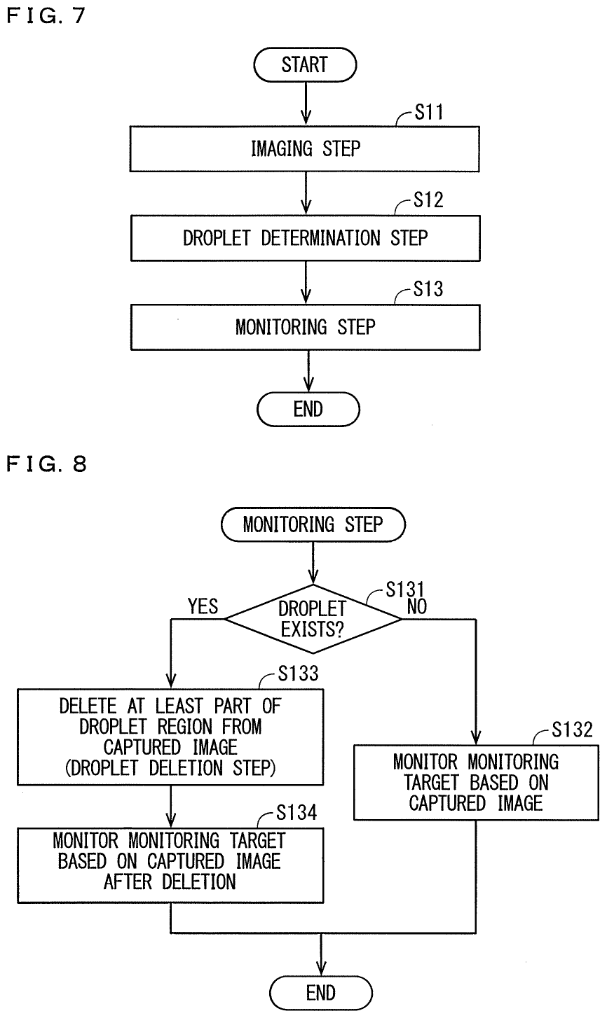

FIG. 7 is a flowchart illustrating an example of the monitoring processing by the processing unit 1. As illustrated in FIG. 7, the camera 70 captures the image of the imaging region including the outer guard 43 as an example of the monitoring target to generate the captured image, and outputs the captured image to the controller 9 (step S11: imaging step). At this point, the imaging step is performed after the end of the guard descending step (step S5). That is, after the controller 9 outputs a control signal to the guard ascending and descending mechanism 55, the camera 70 captures the image of the imaging region. When the guard ascending and descending mechanism 55 can normally move the guards 41 to 43 to each guard standby position, the captured image includes the outer guard 43 normally located at the guard standby position (see FIG. 6).

Subsequently, the monitoring processing part 92 determines whether the droplet L1 is included in the captured image obtained in the imaging step (step S12: droplet determination step). In this case, because the monitoring processing part 92 monitors the state of the outer guard 43 based on the guard determination regions R11, R12, it may be determined whether the droplets L1 are included in the guard determination regions R11, R12. Hereinafter, the monitoring processing part 92 determines existence or non-existence of the droplet L1 in the guard determination regions R11, R12. For example, the monitoring processing part 92 may determine the existence or non-existence of the droplet L1 by performing the image processing described below on the captured image.

First, the monitoring processing part 92 performs edge detection processing such as the Canny method on the captured image to generate an edge image. For example, this edge image is a binary image, and a pixel value of a pixel indicating an edge has a large value, and the pixel value of the pixel not indicating the edge has a small value. When the captured image does not include the droplet L1, the edge image does not include the edge of the droplet L1, but includes the edge (hereinafter, referred to as a background edge) of the object such as the substrate W. On the other hand, when the captured image includes the droplet L1, the edge image includes both the edge of the droplet L1 and the background edge.

Subsequently, the monitoring processing part 92 obtains a difference image between the edge image and the edge background image. The edge background image is an edge image that does not include the edge of the droplet L1 but includes the background edge. The edge background image is previously set, and for example, stored in the storage 94. For example, such the edge background image does not include the droplet L1, and is obtained by performing the edge detection on the captured image that is captured by the camera 70 while not only the substrate holder 20 holds the substrate W but also the outer guard 43 is normally located at the guard standby position. In the difference image between the edge image and the edge background image, the background edge is almost canceled, and the edge of the droplet L1 remains.

Because the edge of the droplet L1 forms a closed curve, the existence or non-existence of the droplet L1 is determined based on the existence or non-existence of a closed curve edge in the difference image. That is, the monitoring processing part 92 determines whether the edge forming the closed curve exists in the difference image. Specifically, the monitoring processing part 92 obtains the curve shape of the edge while performing contour tracking on the difference image to label each edge. The monitoring processing part 92 determines whether the closed curved edge exists, determines that the droplet L1 is included when the closed curved edge exists, and determines that the droplet L1 is not included when the closed curved edge does not exist. That is, a region surrounded by the closed curved edge is the droplet region RL1. When detecting a plurality of closed curved edges, the monitoring processing part 92 sets a region surrounded by each edge as the droplet region RL1.

Subsequently, the monitoring processing part 92 determines whether at least a part of the droplet region RL1 is included in at least one of the guard determination regions R11, R12. When at least a part of the droplet region RL1 is included in any one of the guard determination regions R11, R12, the monitoring processing part 92 determines that the droplet L1 is included in the guard determination region R1.

The monitoring processing part 92 may determine the existence or non-existence of the droplet L1 in the captured image by an algorithm other than the above algorithm. For example, the monitoring processing part 92 may determine whether the droplet L1 is included in the captured image using the learned model. For example, such the learned model is generated by machine learning such as deep learning. The learned model classifies the captured image into a category including the droplet L1 and a category not including the droplet L1. The learned model is generated by the machine learning of a learning model with a plurality of teaching data including a plurality of learning image data including the droplet L1, a plurality of learning image data not including the droplet L1, and a correct category (label) for the learning image data.

Subsequently, the monitoring processing part 92 monitors the state of the outer guard 43 based on the captured image by an algorithm according to the determination result of the existence or non-existence of the droplet L1 (step S13: monitoring step).

FIG. 8 is a flowchart illustrating a specific example of the monitoring step. As described above, the monitoring processing part 92 determines whether the droplet L1 is included in the captured image (in this case, the guard determination region R1) (step S131). When the droplet L1 is not included, the monitoring processing part 92 monitors the outer guard 43 by comparing the guard determination region R1 of the captured image with the reference image M1 (step S132).

Specifically, the monitoring processing part 92 calculates the similarity ratio between the guard determination region R11 and the reference image M11 and the similarity ratio between the guard determination region R12 and the reference image M12, and compares each similarity ratio with a predetermined guard threshold. The similarity ratio is not particularly limited, but for example, may be a known similarity ratio such as a sum of squared differences of pixel values, a sum of absolute differences of pixel values, normalization cross-correlation, or zero-mean normalization cross-correlation. The guard threshold is previously set by the experiment or simulation, and for example, is stored in the storage 94.

The monitoring processing part 92 determines that the outer guard 43 is normally located in the guard standby position when both of the similarity ratios are equal to or greater than the guard threshold, and the monitoring processing part 92 determines that the abnormality is generated with respect to the outer guard 43 when at least one of the similarity ratios is less than the guard threshold. When it is determined that the abnormality is generated, the processing controller 91 may appropriately interrupt the processing on the substrate W. For example, the carry-out of the substrate W by the main conveyance robot 103 may be interrupted. Accordingly, the collision between the main conveyance robot 103 and the outer guard 43 can be avoided. In addition, the processing controller 91 may cause a notification part such as a display (not illustrated) to notify the abnormality. Consequently, a worker can recognize the abnormality.

On the other hand, when it is determined in step S131 that the droplet L1 is included, the monitoring processing part 92 monitors the state of the outer guard 43 using the region that is obtained by removing at least a part of the droplet region RL1 indicating the droplet L1 in the captured image. As a specific example, the monitoring processing part 92 deletes the droplet region RL1 from the captured image to generate removed image data (hereinafter, referred to as a removed image) (step S133: droplet deletion step). At this point, the deletion of the region includes setting of the pixel value of each pixel in the region as a specified value. For example, the monitoring processing part 92 sets all pixel values of the pixels belonging to the droplet region RL1 in the captured image to zero.

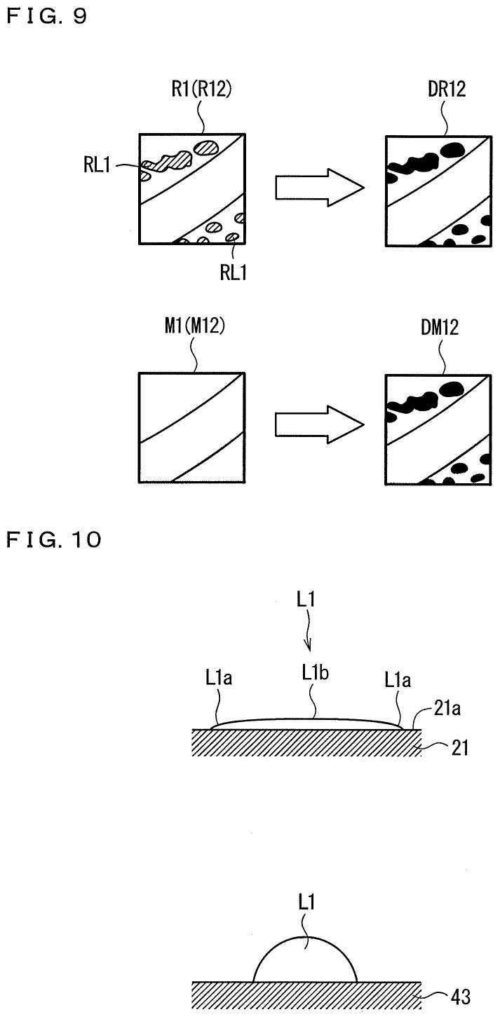

FIG. 9 is a view schematically illustrating an example of a state in which the droplet deletion step is performed on the captured image and the reference image. In the example of FIG. 6, the droplet L1 is not included in the guard determination region R11, and the droplet L1 is included in the guard determination region R12. Accordingly, in the example of FIG. 9, the guard determination region R12 and the reference image M12 are illustrated as targets of the droplet deletion.

The monitoring processing part 92 generates a removed image DR12 by deleting the droplet region RL1 in the guard determination region R12. In the example of FIG. 9, the deleted region is illustrated in black in the removed image DR12. The monitoring processing part 92 also deletes the same region as the droplet region RL1 from the reference image M12 to generate removed reference image data (hereinafter, referred to as a removed reference image) DM12. Also in the removed reference image DM12, the pixel value of the pixel in the same region as the droplet region RL1 is the specified value (for example, zero).

In the example of FIG. 6, because the droplet L1 is not included in the guard determination region R11, the droplet region is not deleted with respect to the guard determination region R11 and the reference image M11.

Subsequently, the monitoring processing part 92 monitors the position of the outer guard 43 based on the captured image after the deletion (step S134). More specifically, the monitoring processing part 92 monitors the position of the outer guard 43 based on the comparison between the guard determination region R11 and the reference image M11 and the comparison between the removed image DR12 and the removed reference image DM12. For example, first, the monitoring processing part 92 calculates the similarity ratio between the guard determination region R11 and the reference image M11 and the similarity ratio between the removed image DR12 and the removed reference image DM12. Subsequently, the monitoring processing part 92 determines whether both of the similarity ratios are equal to or greater than a predetermined guard threshold. The monitoring processing part 92 determines that the outer guard 43 is normally located in the guard standby position when both of the similarity ratios are equal to or greater than the guard threshold, and the monitoring processing part 92 determines that the abnormality is generated with respect to the outer guard 43 when at least one of the similarity ratios is less than the guard threshold.

As described above, when the droplet L1 is included in the captured image, the monitoring processing part 92 monitors the state of the monitoring target using the region excluding the droplet region RL1 in the captured image. In the above example, the monitoring processing part 92 monitors the outer guard 43 based on the comparison between the removed image DR12 obtained by deleting the droplet region RL1 from the guard determination region R12 and the removed reference image DM12 obtained by deleting the droplet region RL1 from the reference image M12. In the comparison between the removed image DR12 and the removed reference image DM12, because the pixel value in the droplet region RL1 is not used, the droplet L1 hardly affects the similarity ratio that is the comparison result. That is, the monitoring processing part 92 can monitor the state of the monitoring target with higher accuracy by reducing the influence of the droplets.

### Second Embodiment

An example of a configuration of the substrate processing apparatus 100 according to a second embodiment is similar to that of the first embodiment. However, in the second embodiment, the controller 9 changes a deletion range of the droplet region RL1 according to the wettability of the surface to which the droplet L1 is attached. At this point, the upper surface 21a of the spin base 21 is a hydrophilic surface having high wettability, and the outer peripheral surface of the outer guard 43 is a hydrophobic surface having lower wettability than that of the upper surface 21a.

FIG. 10 is a sectional view schematically illustrating an example of the droplet L1 on the upper surface 21a of the spin base 21 and the outer peripheral surface of the outer guard 43. Because of the low wettability of the outer peripheral surface of the outer guard 43, the droplet L1 is positioned on the outer peripheral surface of the outer guard 43 in the thickly raised state due to surface tension. At this point, the droplet L1 is colorless and transparent. In this case, the droplet L1 in the thickly raised state functions as a lens. For this reason, distortion is generated in the image of the outer peripheral surface of the outer guard 43 visually recognized through the droplet L1. Accordingly, when the droplet region RL1 indicating the droplet L1 adhered to the surface having the low wettability is used for monitoring the outer guard 43, the monitoring accuracy may be deteriorated. Consequently, it is desirable to delete the entire droplet region RL1 corresponding to the surface having the low wettability.

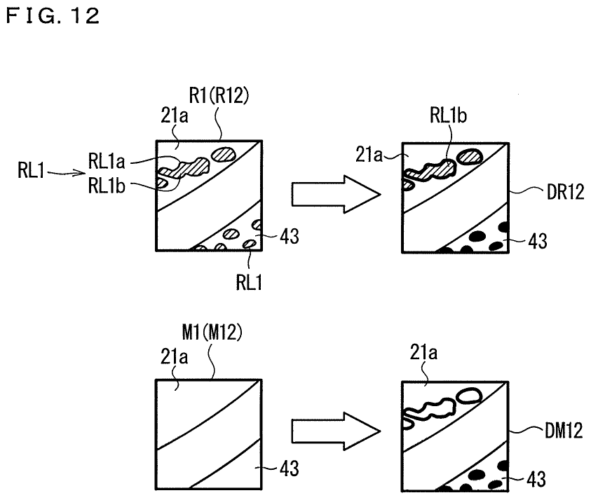

On the other hand, because the wettability of the upper surface 21a of the spin base 21 is higher than the wettability of the outer peripheral surface of the outer guard 43, the droplet L1 spreads thinly on the upper surface 21a as illustrated in FIG. 10. Although a contour portion L1a of such the droplet L1 in planar view can function as the lens, the liquid surface of an inner portion L1b inside the contour portion L1a is relatively flat, so that the inner portion L1b is difficult to function as the lens. For this reason, although the distortion may be generated in the image of the upper surface 21a of the spin base 21 visually recognized through the contour portion L1a, the distortion is hardly generated in the image of the upper surface 21a of the spin base 21 visually recognized through the inner portion L1b. Accordingly, for the droplet region RL1 indicating the droplet L1 adhered to the surface having the high wettability, it is desirable to delete only a contour region RL1a (see also FIG. 12).

In the second embodiment, the controller 9 varies the deletion range of the droplet region RL1 according to the wettability of the surface to which the droplet L1 is adhered.

In this case, as an example, the region data is previously recorded in the storage 94. The region data is data indicating a first region and a second region corresponding to surfaces of different objects in the captured image. The first region is a region corresponding to the hydrophilic surface having the high wettability, and the second region is a region corresponding to the hydrophobic surface having the low wettability. As a more specific example, the first region includes the upper surface 21a of the spin base 21, and the second region includes the outer peripheral surface of the outer guard 43. The region data may include data indicating a pixel group belonging to the first region and data indicating a pixel group belonging to the second region. Such the region data may be previously set by an operator. Hereinafter, the first region is also referred to as a hydrophilic region, and the second region is also referred to as a hydrophobic region.

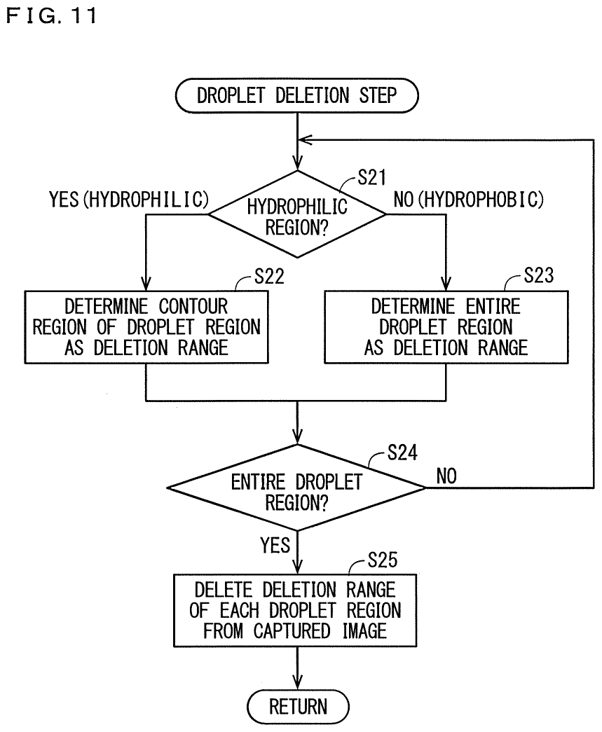

An example of the monitoring processing according to the second embodiment is similar to the flowcharts of FIGS. 7 and 8. However, a specific example of the droplet deletion step in step S133 is different from that of the first embodiment. FIG. 11 is a flowchart illustrating a specific example of the droplet deletion step according to the second embodiment.

The monitoring processing part 92 determines whether the certain droplet region RL1 is included in the hydrophilic region or the hydrophobic region (step S21). In other words, the monitoring processing part 92 determines whether the surface to which the droplet L1 is adhered is the hydrophilic surface or the hydrophobic surface. As a more specific example, the monitoring processing part 92 reads the region data from the storage 94, and compares each of the hydrophilic region and the hydrophobic region indicated by the region data with the droplet region RL1 to make a determination. When the droplet region RL1 is included in the hydrophilic region, the monitoring processing part 92 determines the contour region RL1a of the droplet region RL1 as the deletion range (step S22). At this point, as an example, the deletion range of the droplet region RL1 included in the upper surface 21a of the spin base 21 is determined to be the contour region RL1a (see also FIG. 12). For example, a width of the contour region RLa can be previously defined by the simulation or experiment. On the other hand, when the droplet region RL1 is included in the hydrophobic region, the monitoring processing part 92 determines the entire droplet region RL1 as the deletion range (step S23). At this point, as an example, the deletion range of the droplet region RL1 included in the outer peripheral surface of the outer guard 43 is determined to be the entire droplet region RL1 (see also FIG. 12).

Subsequently, the monitoring processing part 92 determines whether the deletion range is determined for all the droplet regions RL1 included in the guard determination region R1 in the captured image (step S24).

When the deletion ranges of all the droplet regions RL1 are not determined, the monitoring processing part 92 performs steps S21 to S24 for the next droplet region RL1.

When the deletion ranges of all the droplet regions RL1 are determined, the monitoring processing part 92 deletes the deletion ranges of all the droplet regions RL1 from the captured image and generates the removed image data (step S25). In addition, the monitoring processing part 92 deletes the same region as the deletion range of all the droplet regions RL1 from the reference image M1.

FIG. 12 is a view schematically illustrating an example of the state in which the droplet deletion step is performed on the captured image and the reference image. In the example of FIG. 6, the droplet L1 is not included in the guard determination region R11, and the droplet L1 is included in the guard determination region R12. Accordingly, in the example of FIG. 12, the guard determination region R12 and the reference image M12 are illustrated as targets of the droplet deletion.

The upper surface 21a of the spin base 21 in the guard determination region R12 corresponds to the hydrophilic region having the high wettability, so that the contour region RL1a of the droplet region RL1 is deleted in the hydrophilic region of the removed image DR12. On the other hand, an inner region RL1b of the droplet region RL1 remains without being deleted. Although the droplet L1 is included in the inner region RL1b, the droplet L1 in the inner region RL1b does not function as the lens so much, so that the image of the upper surface 21a of the spin base 21 visually recognized through the droplet L1 is not distorted so much and the upper surface 21a appears as it is.

The outer peripheral surface of the outer guard 43 in the guard determination region R12 corresponds to the hydrophobic region having the low wettability, so that the entire droplet region RL1 is deleted in the hydrophobic region of the removed image DR12.

Also in the removed reference image DM12, the same region as the contour region RL1a of the droplet region RL1 is deleted in the hydrophilic region, and the same region as the entire droplet region RL1 is deleted in the hydrophobic region.

Subsequently, similarly to the first embodiment, the monitoring processing part 92 monitors the position of the outer guard 43 based on the captured image after removal (step S134). Specifically, the monitoring processing part 92 monitors the position of the outer guard 43 by comparing the guard determination region R11 with the reference image M11 and comparing the removed image DR12 with the removed reference image DM12.

As described above, for the droplet region RL1 indicating the droplet L1 adhered to the hydrophilic surface, the monitoring processing part 92 monitors the outer guard 43 using the region excluding the contour region RL1a in the captured image (more specifically, the guard determination region R1). Conversely, the monitoring processing part 92 monitors the position of the outer guard 43 also using the inner region RL1b of the droplet region RL1. That is, in the inner region RL1b where the liquid level of the colorless and transparent droplet L1 is flat, the outer peripheral surface of the outer guard 43 is substantially reflected as it is, and thus, the monitoring processing part 92 monitors the position of the outer guard 43 also using the inner region RL1b. For this reason, the position of the outer guard 43 can be monitored based on more appropriate pixel values in the guard determination region R1, and the position of the outer guard 43 can be monitored with higher accuracy. More specifically, the similarity ratio between the removed image DR12 and the removed reference image DM12 can be calculated by comparing more appropriate pixel values, so that the similarity ratio can be calculated with higher accuracy and the position of the outer guard 43 can be monitored with higher accuracy.

On the other hand, for the droplet region RL1 indicating the droplet L1 adhered to the hydrophobic surface having the low wettability, the monitoring processing part 92 monitors the position of the outer guard 43 using the region obtained by excluding the entire droplet region RL1 in the captured image (more specifically, the guard determination region R1). This can avoid the decrease in similarity ratio due to the droplet region RL1 in which the image of the outer peripheral surface of the outer guard 43 is distorted, and the similarity ratio can be calculated with higher accuracy. Accordingly, the position of the outer guard 43 can be monitored with higher accuracy.

Moreover, in the above example, the monitoring processing part 92 determines the wettability of the surface based on the region data. According to this, the monitoring processing part 92 can determine the wettability of the surface by simpler processing.

### <Temporal Change>

The wettability of the upper surface 21a of the spin base 21 and the wettability of the outer peripheral surface of the outer guard 43 may change over time. For example, when the processing liquid adheres to the upper surface 21a of the spin base 21 and the outer peripheral surface of the outer guard 43, the wettability may gradually change. The wettability increases or decreases depending on the kind of the processing liquid, the material of the upper surface 21a of the spin base 21, and the material of the outer peripheral surface of the outer guard 43.

Such the temporal change in wettability can be previously measured by the experiment or simulation. Thus, the monitoring processing part 92 may update the region data according to the temporal change.

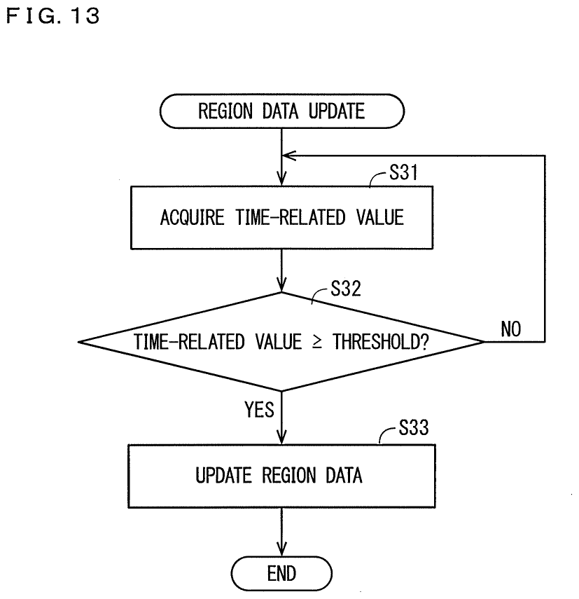

FIG. 13 is a flowchart illustrating an example of the update of the region data. First, the monitoring processing part 92 acquires a time-related value such as an operation time of the substrate processing apparatus 100 (step S31). The operation time here is an accumulated time during which the substrate processing apparatus 100 operates. For example, such the accumulated time is measured based on a known timer circuit. The time-related value may include at least one of an elapsed time and the number of processed substrates W in addition to the operation time of the substrate processing apparatus 100. The elapsed time here is time that elapses regardless of whether the substrate processing apparatus 100 operates. The number of processed substrates W is the number of substrates W that the substrate processing apparatus 100 completes the processing. For example, the controller 9 can measure the number of processed substrates by incrementing the number of processed substrates each time the indexer robot 102 takes out the substrates W.

Subsequently, the monitoring processing part 92 updates the region data based on the time-related value. Specifically, the monitoring processing part 92 determines whether the time-related value is equal to or greater than a predetermined time threshold (step S32). For example, the time threshold is previously set and stored in the storage 94 by the simulation or experiment. When the time-related value is less than the time threshold, the monitoring processing part 92 executes step S31 again.

When the time-related value is equal to or greater than the predetermined time threshold, the monitoring processing part 92 updates the region data (step S33). As a more specific example, in the case where the wettability of the outer peripheral surface of the outer guard 43 increases with the lapse of time, the operation of the monitoring processing part 92 is defined to update the region data as follows. That is, when the time-related value is equal to or more than the time threshold, the monitoring processing part 92 changes the region indicating the outer peripheral surface of the outer guard 43 from the hydrophobic region to the hydrophilic region in the region data. On the other hand, in the case where the wettability of the upper surface 21a of the spin base 21 decreases with the lapse of time, the operation of the monitoring processing part 92 is defined to update the region data as follows. That is, when the time-related value is equal to or more than the time threshold, the monitoring processing part 92 changes the region indicating the upper surface 21a of the spin base 21 from the hydrophilic region to the hydrophobic region in the region data. A different value may be adopted as the time threshold according to the surface of each object in the captured image.

As described above, the monitoring processing part 92 updates the region data according to the temporal change in the wettability of the surface of the object included in the imaging region. Accordingly, the monitoring processing part 92 can appropriately determine the deletion range of the droplet region RL1 according to the temporal change.

### <Wettability Determination>

In the above example, the region data indicating the wettability of the surface of the object in the imaging region is previously set and stored in the storage 94. However, the present embodiment is not necessarily limited thereto. As described below, the monitoring processing part 92 may determine high and low of wettability based on the captured image.

As can be understood from FIG. 10, the droplet L1 on the surface having the low wettability is positioned in the thick raised state. On the surface having the low wettability, the spherical droplets L1 do not spread so much, and the plurality of droplets L1 are finely separated and exist when the amount of liquid supplied to the surface is large. That is, the size of the droplet L1 in planar view on the surface having the low wettability is relatively small. On the other hand, because the droplet L1 on the surface having the high wettability spreads thinly and widely, the size of the droplet L1 in planar view is relatively large.

Thus, the monitoring processing part 92 may obtain the size of the droplet L1 based on the captured image, and determine the wettability of the surface to which the droplet L1 is attached based on the size. In other words, the monitoring processing part 92 may determine the deletion range of the droplet region RL1 based on the size of the droplet L1.

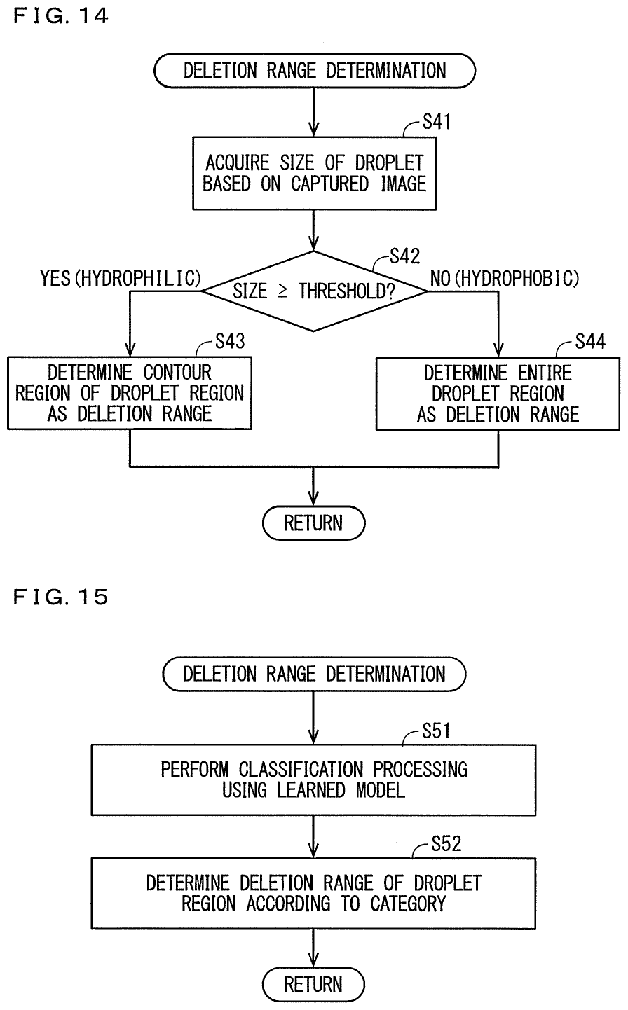

FIG. 14 is a flowchart illustrating an example of a method for determining the deletion range based on the size. First, the monitoring processing part 92 obtains the size of the droplet region RL1 based on the captured image (step S41). Specifically, the monitoring processing part 92 obtains the number of pixels configuring the droplet region RL1 as the size of the droplet region RL1.

Subsequently, the monitoring processing part 92 determines whether the size of the droplet region RL1 is equal to or greater than a predetermined wettability threshold (corresponding to the first threshold) (step S42). For example, the wettability threshold is previously set and is stored in the storage 94.

On the other hand, when the size of the droplet region RL1 is equal to or larger than the wettability threshold, the monitoring processing part 92 determines the deletion range of the droplet region RL1 as the contour region RL1a (step S43). That is, when the size is equal to or larger than the wettability threshold, it is considered that the droplet region RL1 is in the hydrophilic region having the high wettability, and thus the deletion range is determined as the contour region RL1a.

When the size of the droplet region RL1 is less than the wettability threshold, the monitoring processing part 92 determines the deletion range of the droplet region RL1 as the entire droplet region RL1 (step S44). That is, when the size is less than the wettability threshold, it is considered that the droplet region RL1 is in the hydrophobic region having low wettability, and thus the deletion range is determined as the entire droplet region RL1.

Accordingly, the monitoring processing part 92 can automatically determine the deletion range of the droplet region RL1 based on the captured image. The operator does not need to previously set the wettability of the surface, so that the previous setting of the region data can be further simplified.

Because the position of each object in the captured image can be previously determined to some extent, the region data indicating the region of each object in the captured image may be previously set. In this region data, the region of each object in the captured image is set, but information about the wettability in the region is not included. In explanation of the example of FIG. 6, the region data includes the region indicating the upper surface 21a of the spin base 21 and the region indicating the outer peripheral surface of the outer guard 43. However, the region data does not include information about the wettability of these regions.

When the size of at least one of the plurality of droplet regions RL1 on the surface (for example, the upper surface 21a of the spin base 21) of a certain object indicated by the region data is equal to or larger than the wettability threshold, the monitoring processing part 92 may determine the deletion range of the plurality of droplet regions RL1 on the surface as the contour region RL1a. When all the sizes of the plurality of droplet regions RL1 on the surface (for example, the outer peripheral surface of the outer guard 43) of another object indicated by the region data are less than the wettability threshold, the monitoring processing part 92 may determine the deletion range of the plurality of droplet regions RL1 on the surface as the entire droplet region RL1.

In the above example, the monitoring processing part 92 determines the wettability based on the size of the droplet region RL1, so that the monitoring processing part 92 can determine the wettability with a relatively light processing load.

However, the method for determining the deletion range is not necessarily limited to the above example. For example, the monitoring processing part 92 may determine the wettability of the surface of each object based on the captured image using the learned model. For example, the learned model is generated by the learning model learning using a plurality of teacher data including a plurality of captured images (learning image data) including the droplet L1 on the upper surface 21a of the spin base 21 and labels (correct categories for wettability) of the plurality of captured images and a plurality of teacher data including a plurality of captured images including the droplet L1 and labels on the outer peripheral surface of the outer guard 43. The wettability can be determined with high accuracy using the learned model.

FIG. 15 is a flowchart illustrating an example of the method for determining the deletion range using the learned model. The monitoring processing part 92 performs classification processing using the learned model (step S51). For example, the monitoring processing part 92 performs the classification processing for each surface of the object in the captured image. For example, when the droplet region RL1 is included in the region corresponding to the upper surface 21a of the spin base 21, the monitoring processing part 92 classifies the region into one of the hydrophilic category and the hydrophobic category using the learned model. Similarly, when the droplet region RL1 is included in the region corresponding to the outer peripheral surface of the outer guard 43, the monitoring processing part 92 classifies the region into one of the hydrophilic category and the hydrophobic category using the learned model. That is, a category indicating hydrophilic and hydrophobic for each of a plurality of surfaces (in this case, the upper surface 21a of the spin base 21 and the outer peripheral surface of the outer guard 43) is prepared as the category of the classification.

The monitoring processing part 92 determines the category, and determines the deletion range of the droplet region RL1 according to the category (step S52). Specifically, the monitoring processing part 92 determines the contour region RL1a of the droplet region RL1 as the deletion range for the droplet L1 adhering to the hydrophilic surface, and determines the entire droplet region RL1 as the deletion range for the droplet L1 adhering to the hydrophobic surface.

### Third Embodiment

In the processing unit 1, the droplet L1 may adhere to the surface of the camera guard 72. For example, sometimes the volatile component of the processing liquid in the chamber 10 is cooled and condensed on the surface of the camera guard 72 (specifically, the surface on the processing space side) and the droplet L1 adheres to the surface of the camera guard 72. Thus, in a third embodiment, the decrease in the accuracy of the monitoring processing due to the droplet L1 of the camera guard 72 is reduced.

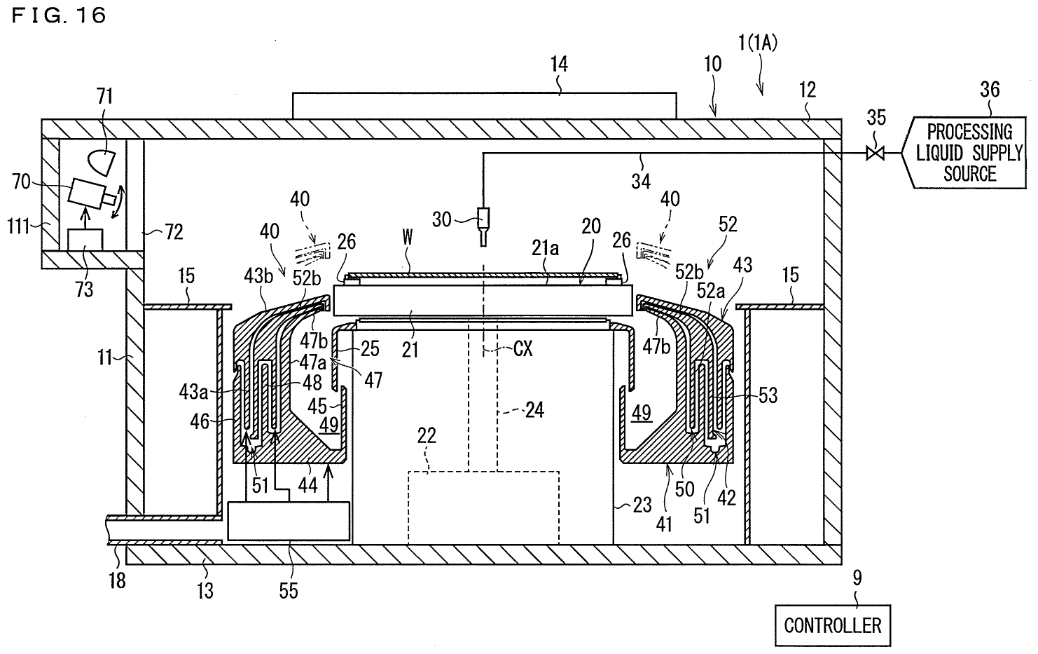

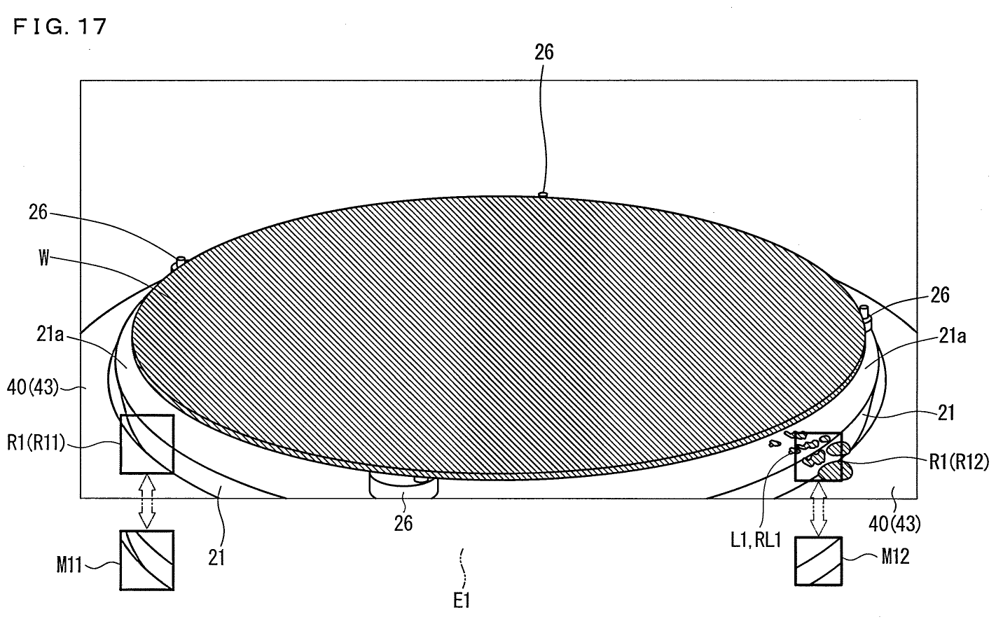

FIG. 16 is a longitudinal sectional view schematically illustrating the example of the configuration of the processing unit 1 according to the third embodiment. Hereinafter, the processing unit 1 according to the third embodiment is referred to as a processing unit 1A. The processing unit 1A further includes a camera displacement part 73 as compared with the processing unit 1 according to the first and second embodiments.

For example, the camera displacement part 73 includes a motor, and displaces the camera 70 between a first camera position and a second camera position. For example, the camera displacement part 73 may rotate the camera 70. In this case, the first camera position and the second camera position are represented by angles about the rotation axis of the camera 70. For example, a movable angle range of the camera 70 is set to about several degrees to several tens of degrees. In this case, as an example, the camera displacement part 73 rotates the camera 70 around a horizontal rotation axis. When the camera displacement part 73 rotates the camera 70, the imaging direction of the camera 70 turns within a predetermined angle range around the rotation axis of the camera 70.

The camera 70 captures the image of the imaging region at the first camera position and then captures the image of the imaging region at the second camera position. Because the first camera position and the second camera position are different from each other, the imaging regions at the first camera position and the imaging region at the second camera position are different from each other.

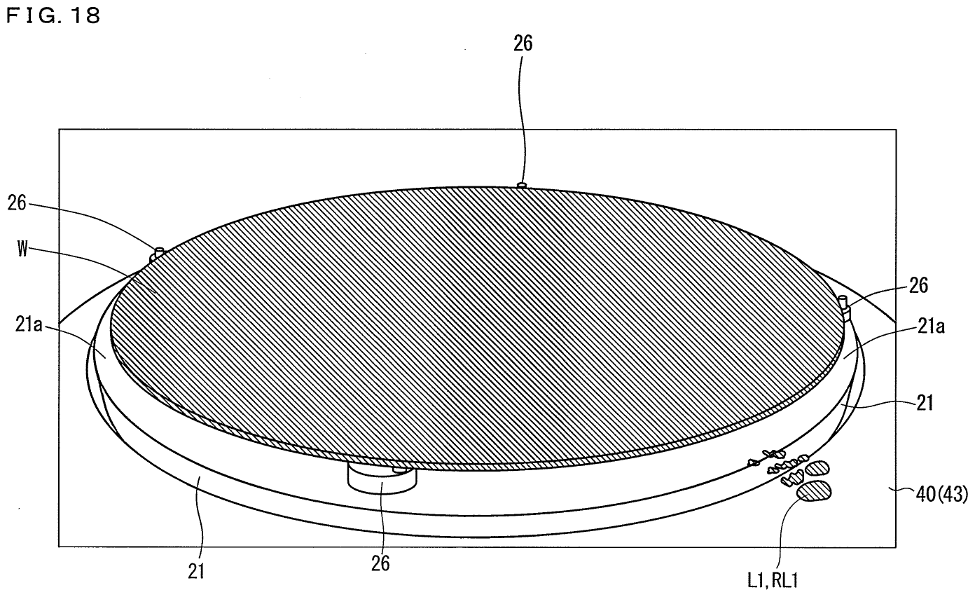

FIG. 17 is a view schematically illustrating an example of the captured image when the camera 70 captures the image at the first camera position, and FIG. 18 is a view schematically illustrating an example of the captured image when the camera 70 captures the image at the second camera position. FIGS. 17 and 18 illustrate the captured images when the droplet L1 adheres to the surface of the camera guard 72.

The rotation axis of the camera 70 extends horizontally, and in this case, the imaging direction at the second camera position is directed downward with respect to the imaging direction at the first camera position. Accordingly, each object in the captured image of FIG. 18 moves in parallel upward with respect to each object in the captured image of FIG. 17. However, the amount of parallel movement depends on the distance between the camera 70 and the object. Specifically, the larger the distance, the larger the amount of parallel movement of the object. That is, the farther the distance from the camera 70, the larger the amount of parallel movement. As illustrated in FIG. 16, because the distance between the camera 70 and the camera guard 72 is the shortest as compared with the distance between the camera 70 and another object in the processing space, the amount of parallel movement of the droplet L1 attached to the camera guard 72 becomes the smallest. Specifically, although the positions of the substrate W, the substrate holder 20, and the outer guard 43 in the captured image greatly change between the captured image of FIG. 17 and the captured image of FIG. 18, the change in the position of the droplet region RL1 in the captured image is smaller than these.

Conversely, when the difference between the positions of the droplets L1 in the captured images at the first camera position and the second camera position is relatively small, it can be considered that the droplet L1 adheres to the camera guard 72. On the other hand, when the difference between the positions of the droplets L1 in the captured images at the first camera position and the second camera position is relatively large, it can be considered that the droplet L1 adheres to the object different from the camera guard 72.

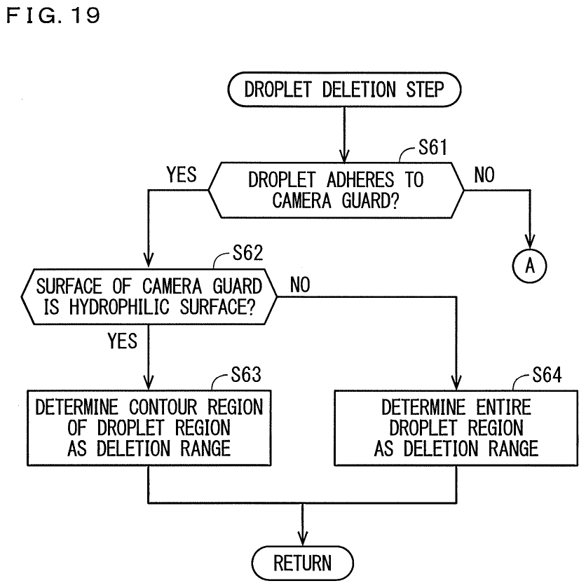

An example of the monitoring processing according to the third embodiment is similar to the flowcharts of FIGS. 7 and 8. However, in the imaging step of step S11, at each of the first camera position and the second camera position, the camera 70 captures the image of the imaging region to generate the captured image. In addition, a specific example of the droplet deletion step in step S132 is different from that of the first embodiment. FIG. 19 is a flowchart illustrating a specific example of the droplet deletion step according to the third embodiment.

First, the monitoring processing part 92 determines whether the droplet L1 adheres to the camera guard 72 based on the captured image (step S61). Specifically, the monitoring processing part 92 determines whether the droplet L1 adheres to the camera guard 72 based on the difference in position between the droplet region RL1 in the captured image at the first camera position and the droplet region RL1 in the captured image at the second camera position. In this case, because the camera displacement part 73 rotates the camera 70 about the horizontal rotation axis, the object in the captured image moves in the vertical direction. Thus, the monitoring processing part 92 obtains the difference in position in the longitudinal direction between the droplet regions RL1 corresponding to the same droplet L1 in both the captured images. For example, the droplet region RL1 corresponding to the same droplet L1 in both captured images can be specified by matching processing. For example, template matching can be adopted as the matching processing.

The monitoring processing part 92 compares the difference between the positions with a predetermined position threshold, and determines that the droplet L1 adheres to the camera guard 72 when the difference is less than the position threshold. For example, the position threshold is previously set by the simulation or experiment and stored in the storage 94.

When the droplet L1 adheres to the camera guard 72, the monitoring processing part 92 determines whether the surface of the camera guard 72 is the hydrophilic surface or the hydrophobic surface (step S62). At this point, as an example, guard data indicating the wettability of the surface of the camera guard 72 is previously stored in the storage 94. The guard data includes data indicating whether the wettability of the surface of the camera guard 72 is high or low, namely, data indicating whether the surface of the camera guard 72 is the hydrophilic surface or the hydrophobic surface. The monitoring processing part 92 reads the guard data from the storage 94 and determines the high and low of the wettability on the surface of the camera guard 72.

When the surface of the camera guard 72 is the hydrophilic surface, the monitoring processing part 92 determines the contour region RL1a of the droplet region RL1 as the deletion range (step S63), and when the surface of the camera guard 72 is the hydrophobic surface, the monitoring processing part 92 determines the entire droplet region RL1 as the deletion range (step S64).

When the droplet L1 does not adhere to the camera guard 72 in step S61, the monitoring processing part 92 may determine the deletion range of the droplet region RL1 according to the region data similarly to the second embodiment.

Subsequently, similarly to the second embodiment, the monitoring processing part 92 monitors the position of the outer guard 43 based on the comparison between the removed image from which the deletion range of the droplet region RL1 is deleted and the reference image (step S134). In the monitoring step, either the captured image at the first camera position or the captured image at the second camera position may be used. The image corresponding to the captured image may be prepared as the reference image.

As described above, in the third embodiment, when the droplet L1 adheres to the camera guard 72, the deletion range of the droplet region RL1 is determined according to the wettability of the camera guard 72. For this reason, the outer guard 43 can be monitored with more appropriate accuracy according to the wettability of the camera guard 72.

The monitoring processing part 92 may update the guard data over time similarly to the region data of the second embodiment. However, in the case where the wettability of the camera guard 72 hardly changes over time, the guard data is not necessarily required. For example, when the camera guard 72 is hydrophilic, the monitoring processing part 92 may delete the contour region RL1a of the droplet region RL1 indicating the droplet L1 attached to the camera guard 72 from the captured image. In this case, the guard data is not read as a matter of course. Similarly, when the camera guard 72 is hydrophobic, the monitoring processing part 92 may delete the entire droplet region RL1 indicating the droplet L1 attached to the camera guard 72 from the captured image. Also in this case, the guard data is not read as a matter of course.

### Fourth Embodiment

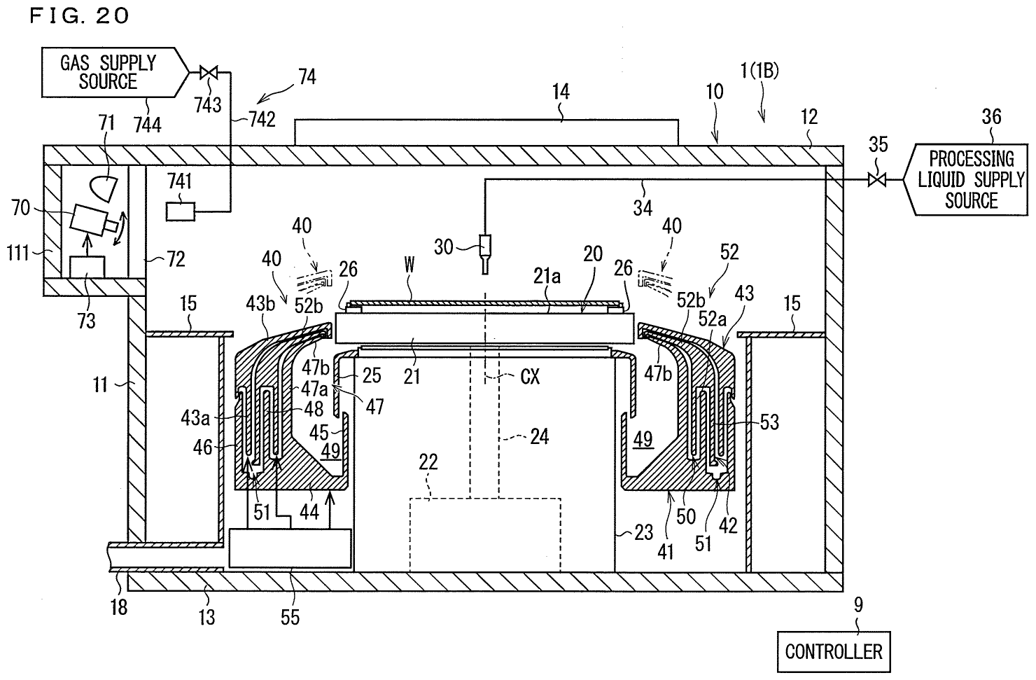

FIG. 20 is a longitudinal sectional view schematically illustrating an example of a configuration of a processing unit 1 according to a fourth embodiment. Hereinafter, the processing unit 1 according to the fourth embodiment is also referred to as a processing unit 1B. The processing unit 1B further includes a droplet remover 74 as compared with the processing unit 1A.

The droplet remover 74 performs a removing operation removing the droplet L1 attached to the surface of the camera guard 72. The term “removal” as used herein only needs to exclude at least a part of the droplet L1 of the camera guard 72, and it is not always necessary to exclude the entire droplet L1.

In the example of FIG. 20, the droplet remover 74 includes a nozzle 741, a gas supply pipe 742, and a valve 743. The nozzle 741 is provided in the processing space of the chamber 10 and discharges gas toward the surface of the camera guard 72. The nozzle 741 is connected to a gas supply source 744 through the gas supply pipe 742. The gas supply source 744 includes a tank that stores the gas, and supplies the gas to the gas supply pipe 742. An inert gas containing at least one of a rare gas such as an argon gas and a nitrogen gas can be employed as the gas. The valve 743 is provided in the gas supply pipe 742. When the valve 743 is open, the gas is supplied from the gas supply source 744 to the nozzle 741 through the gas supply pipe 742, and discharged from the discharge port of the nozzle 741 toward the surface of the camera guard 72. When the gas is blown onto the surface of the camera guard 72, the droplet L1 attached to the camera guard 72 is blown off and removed from the camera guard 72. For example, the flow rate of the gas is set to equal to or greater than about 50 cc/min and equal to or greater than 150 cc/min.

When it is determined that the droplet L1 is included in the captured image, the controller 9 causes the droplet remover 74 to perform the removing operation to remove the droplet L1 from the camera guard 72.

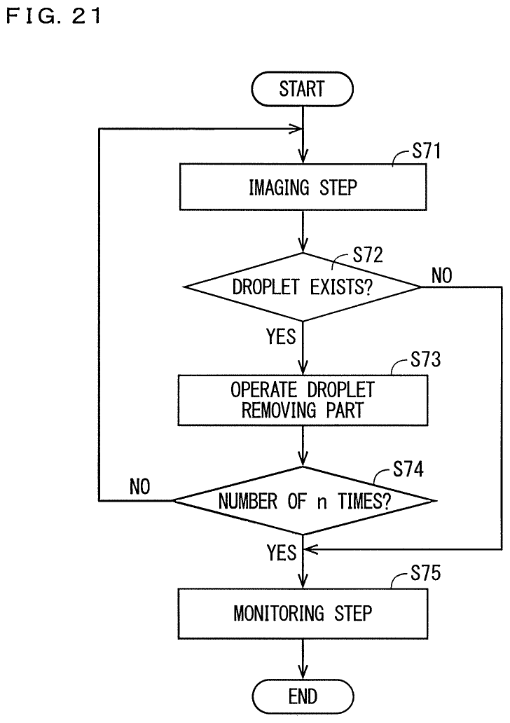

FIG. 21 is a flowchart illustrating an example of the operation of the processing unit 1B according to the fourth embodiment. The camera 70 captures the image of the imaging region to generate the captured image (step S71). Similarly to the third embodiment, the camera 70 may capture the image of the imaging region at each of the first camera position and the second camera position.

Subsequently, the controller 9 determines whether the droplet L1 is included in the captured image (step S72). The controller 9 determines the existence or non-existence of the droplet L1 similarly to the first embodiment.

When it is determined that the droplet L1 is included in the captured image, the droplet remover 74 performs the removing operation (step S73). That is, the valve 743 is open, and the gas is blown onto the surface of the camera guard 72. Consequently, the droplet L1 that may be attached to the camera guard 72 is blown off. In short, when the droplet L1 is included in the captured image, there is a possibility that the droplet L1 adheres to the camera guard 72, so that the droplet remover 74 operates.

Subsequently, the controller 9 determines whether steps S71, S72 are executed a predetermined number of times (step S74). When the predetermined number of times is not executed, the controller 9 performs step S71 again. For example, the predetermined number of times is previously set by the simulation or experiment and stored in the storage 94. The predetermined number of times may be one. In this case, step S74 is unnecessary.

When the droplet L1 is removed by the operation of the droplet remover 74, the droplet L1 is not included in the captured image. For this reason, it is determined in step S72 that the droplet L1 is not included in the captured image. At this point, the monitoring processing part 92 monitors the position of the outer guard 43 based on the captured image without operating the droplet remover 74 any more (step S75). That is, the monitoring processing part 92 monitors the position of the outer guard 43 based on the captured image after the removing operation. In this case, because the droplet L1 is not included, the monitoring processing part 92 monitors the position of the outer guard 43 by the comparison between the guard determination region R11 and the reference image M11 and the comparison between the guard determination region R12 and the reference image M12.

On the other hand, when steps S71, S72 are executed a predetermined number of times, there is a possibility that the droplet L1 is also included in the latest captured image after the removing operation. However, because there is a high possibility that the droplet L1 is removed from the surface of the camera guard 72 by the operation of the droplet remover 74, there is a high possibility that the droplet L1 adheres to the object other than the camera guard 72, for example, the upper surface 21a of the spin base 21 or the outer peripheral surface of the outer guard 43. For this reason, similarly to the first or second embodiment, the monitoring processing part 92 monitors the outer guard 43 based on the captured image after the removing operation (step S75).

Of course, because the possibility of being attached to the camera guard 72 is not zero, the monitoring processing part 92 may monitor the position of the outer guard 43 based on the captured image after the removing operation in the same manner as in the third embodiment in step S75.

As described above, when there is the high possibility that the droplet L1 adheres to the camera guard 72, the droplet L1 of the camera guard 72 can be removed by the droplet remover 74. Accordingly, in the subsequent monitoring step, the influence of the droplet L1 by the camera guard 72 is reduced, and the outer guard 43 can be related with higher accuracy.

In step S71, the camera 70 may capture the images of the imaging region at the first camera position and the second camera position, and in step S72, the controller 9 may determine whether the droplet L1 adheres to the camera guard 72 based on both captured images. In this case, the droplet remover 74 operates when the droplet L1 adheres to the camera guard 72, so that an unnecessary removing operation by the droplet remover 74 can be avoided.

In the above specific example, the droplet remover 74 blows off the droplet L1 with the gas, but the present embodiment is not necessarily limited thereto. For example, the droplet remover 74 may include a wiper body that extends along the surface of the camera guard 72 and a wiper drive part that rotates the wiper body about a proximal end of the wiper body to pivot the wiper body along the surface of the camera guard 72. For example, the wiper drive part includes a motor. According to this, the droplet attached to the camera guard 72 can be more reliably removed.

As described above, the substrate processing apparatus 100 and the monitoring method have been described in detail, but the above description is an example in all aspects, and these are not limited thereto. Innumerable modifications not illustrated can be envisaged without departing from the scope of the present disclosure. The configurations described in the above embodiments and the modifications can appropriately be combined as long as they are not inconsistent with each other.

For example, at least one of the substrate holder 20, the first nozzle 30, the second nozzle 60, the third nozzle 65, the inner guard 41, and the middle guard 42 can be adopted as the monitoring target. In short, any object in the chamber 10 can be adopted as the monitoring target.

### EXPLANATION OF REFERENCE SIGNS

1: processing unit
10: chamber
100: substrate processing apparatus
20: substrate holder (spin chuck)
30: nozzle (first nozzle)
43: monitoring target (outer guard)
60: nozzle (second nozzle)
65: nozzle (third nozzle)
70: camera
72: camera guard
74: droplet remover
9: controller
W: substrate
S11: imaging step (step)
S12: droplet determination step (step)
S13: monitoring step (step)

1. A substrate processing apparatus comprising:
a chamber;
a substrate holder that holds a substrate in said chamber;
a nozzle that discharges a processing liquid toward said substrate held by said substrate holder;
a camera that captures an image of an imaging region including a monitoring target in said chamber to generate captured image data; and
a controller that monitors said monitoring target using a region obtained by removing at least a part of a droplet region indicating a droplet in said captured image data when said captured image data includes the droplet.

2. The substrate processing apparatus according to claim 1, further comprising a storage that stores region data indicating a first region and a second region corresponding to surfaces of different objects in said captured image data,
wherein said controller monitors said monitoring target using a region excluding a contour region of said droplet region in said captured image data when said droplet is included in said first region, and said controller monitors said monitoring target using a region excluding an entire of said droplet region in said captured image data when said droplet is included in said second region.

3. The substrate processing apparatus according to claim 1, wherein said controller monitors said monitoring target using a region excluding a contour region of said droplet region in said captured image data for said droplet attached to a hydrophilic surface and excluding the entire of said droplet region in said captured image data for said droplet attached to a hydrophobic surface having lower wettability than said hydrophilic surface.

4. The substrate processing apparatus according to claim 3, further comprising a storage that stores region data indicating a first region and a second region respectively corresponding to said hydrophilic surface and said hydrophobic surface in said captured image data,
wherein said controller determines whether a surface to which said droplet adheres is said hydrophilic surface or said hydrophobic surface based on said region data.

5. The substrate processing apparatus according to claim 4, wherein said controller updates said region data based on an operation time of said substrate processing apparatus, a number of processed substrates, or a time-related value indicating an elapsed time.

6. The substrate processing apparatus according to claim 3, wherein said controller determines whether a surface to which the droplet adheres is said hydrophilic surface or said hydrophobic surface based on said captured image data.

7. The substrate processing apparatus according to claim 6, wherein said controller calculates a size of said droplet region based on said captured image data, determines that said surface is the hydrophilic surface when the size of said droplet region is equal to or greater than a threshold, and determines that said surface is the hydrophobic surface when the size of said droplet is less than said threshold.

8. The substrate processing apparatus according to claim 6, wherein said controller determines whether said surface is said hydrophilic surface or said hydrophobic surface using a learned model.

9. The substrate processing apparatus according to claim 1, further comprising a hydrophilic and transparent camera guard provided between said camera and said imaging region,
wherein said controller determines whether said droplet adheres to said camera guard based on said captured image data, and monitors said monitoring target using a region obtained by excluding a contour region of said droplet region indicating said droplet adhering to said camera guard from said captured image data when said droplet adheres to said camera guard.

10. The substrate processing apparatus according to claim 1, further comprising a hydrophilic and transparent camera guard provided between said camera and said imaging region,
wherein said controller determines whether said droplet adheres to said camera guard based on said captured image data, and monitors said monitoring target using a region obtained by excluding the entire of said droplet region indicating said droplet adhering to said camera guard from said captured image data when said droplet adheres to said camera guard.

11. The substrate processing apparatus according to claim 1, further comprising:
a transparent camera guard provided between said camera and said imaging region; and
a droplet remover that performs a removing operation removing at least a part of said droplet attached to said camera guard,
wherein when said captured image data includes said droplet, said droplet remover performs said removing operation and said controller monitors said monitoring target based on said captured image data captured by the camera after the removing operation.

12. A monitoring method comprising:
an imaging step of generating captured image data by a camera capturing an image of an imaging region including a monitoring target in a chamber, the chamber accommodating a substrate holder that holds a substrate and a nozzle that discharges a processing liquid toward said substrate held by said substrate holder;
a droplet determination step of determining whether a droplet is included in said captured image data; and
a monitoring step of monitoring said monitoring target using a region obtained by removing at least a part of a droplet region indicating said droplet in said captured image data when said droplet is included in said captured image data.
